(19) United States
(12) Patent Application Publication
(10) Pub. No.: US 2026/0177923 A1
(43) Pub. Date: Jun. 25, 2026

(54) PATTERN FORMATION METHOD USING RESIST COMPOSITION

(71) Applicant: Samsung Electronics Co., Ltd., Suwon-si (KR)

(72) Inventors: Haengdeog KOH, Suwon-si (KR); Beomseok KIM, Suwon-si (KR); Youngmin NAM, Suwon-si (KR); Sunyoung LEE, Suwon-si (KR); Jiyoun LEE, Suwon-si (KR); Changheon LEE, Suwon-si (KR); Jinwon JEON, Suwon-si (KR); Jungha CHAE, Suwon-si (KR); Minyoung HA, Suwon-si (KR); Sunghyun HAN, Suwon-si (KR)

(73) Assignee: Samsung Electronics Co., Ltd., Suwon-si (KR)

(21) Appl. No.: 19/217,248

(22) Filed: May 23, 2025

(30) Foreign Application Priority Data
Dec. 24, 2024 (KR) 10-2024-0196072

(51) Int. Cl. G03F 7/32; G03F 7/004

(52) U.S. Cl. CPC G03F 7/325; G03F 7/0044; G03F 7/0048

(57) ABSTRACT

Provided is a pattern formation method including forming a resist film by applying a resist composition including an organometallic compound and an additive, forming an exposed portion and an unexposed portion by exposing at least a portion of the resist film to high-energy rays, and developing the exposed resist film by using a developer, wherein i) the developer is a hydrophobic developer, and the unexposed portion is removed in the developing; or ii) the developer is a hydrophilic developer, and the exposed portion is removed in the developing. The organometallic compound is represented by formula 1, and the additive is represented by formula 2.

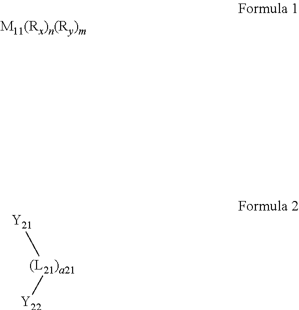

wherein, for descriptions of M₁₁, Rₓ, R_{y}, n, m, Y₂₁, Y₂₂, L₂₁, and a21 in Formulas 1 and 2, reference may be made to the specification.

### CROSS-REFERENCE TO RELATED APPLICATION

This application is based on and claims priority under 35 U.S.C. § 119 to Korean Patent Application No. 10-2024-0196072, filed on Dec. 24, 2024, in the Korean Intellectual Property Office, the disclosure of which is incorporated by reference herein in its entirety.

### BACKGROUND

### 1. Field

The disclosure relates to a pattern formation method using a resist composition.

### 2. Description of the Related Art

During the manufacturing of semiconductors, resists, of which physical properties change in response to light, may be used to form fine patterns. Among these resists, chemically amplified resists have been widely used. With chemically amplified resists, acids formed when light reacts with photoacid generators react again with base resins to change the solubility of the base resins in developers, thereby enabling patterning.

However, in the case of a chemically amplified resist, the formed acid may also diffuse to an unexposed region, which may cause problems, such as a reduction in uniformity of patterns and/or an increase in surface roughness. In addition, as semiconductor processes become increasingly miniaturized, since acid diffusion is not easy to control, developments in new types of resist are being explored.

### SUMMARY

Provided is a pattern formation method using a resist composition of which properties change according to the hydrophilicity of a developer.

Additional aspects will be set forth in part in the description which follows and, in part, will be apparent from the description, or may be learned by practice of the presented embodiments of the disclosure.

According to an aspect of the disclosure, a pattern formation method includes forming a resist film by applying a resist composition including an organometallic compound represented by Formula 1 below and an additive represented by Formula 2 below,
forming an exposed portion of the resist film and an unexposed portion of the resist film by exposing at least a portion of the resist film to high-energy rays, and
developing the exposed resist film by using a developer,
wherein i) the developer is a hydrophobic developer, and the unexposed portion is removed in the developing; or
ii) the developer is a hydrophilic developer, and the exposed portion is removed in the developing:

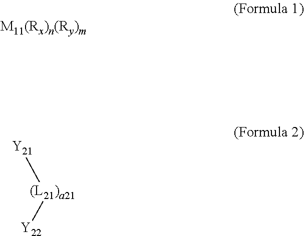

wherein, in Formulas 1 and 2,
M₁₁ is at least one of indium (In), tin (Sn), antimony (Sb), tellurium (Te), thallium (Tl), lead (Pb), bismuth (Bi), or polonium (Po),
Rₓ is *—X₁—Y₁,
R_{y} is *-(L₁)ₐ₁-(R₁)_{b1},
n is an integer from 0 to 6,
m is an integer from 1 to 6,
m+n is 6 or less,
a plurality of Rₓ are identical to or different from each other,
a plurality of R_{y} are identical to or different from each other,
X₁ is at least one of O, OC(═O), C(═O)O, OS(═O), S(═O)O, OS(═O)₂, S(═O)₂O, S, SC(═O), or C(═O)S,
Y₁ is at least one of hydrogen, deuterium, or a linear, branched, or cyclic C₁-C₃₀ monovalent hydrocarbon group optionally containing a heteroatom,
L₁ is a linear, branched, or cyclic C₁-C₃₀ divalent hydrocarbon group optionally containing a heteroatom,
a1 is an integer from 0 to 4,
R₁ is a linear, branched, or cyclic C₁-C₃₀ monovalent hydrocarbon group optionally containing a heteroatom, wherein two adjacent groups in a plurality of R₁ are optionally bonded to each other to form a condensed ring,
b1 is an integer from 1 to 4,
Y₂₁ and Y₂₂ are each independently a linear, branched, or cyclic C₁-C₃₀ divalent hydrocarbon group including one or more selected from an oxygen atom, a sulfur atom, a nitrogen atom, and a phosphorus atom as a heteroatom,
L₂₁ is a single bond, a double bond, or a linear, branched, or cyclic C₁-C₃₀ divalent hydrocarbon group,
each a21 is independently an integer from 1 to 4, and
adjacent two of Y₂₁, Y₂₂, and L₂₁ are optionally bonded to each other to form a condensed ring.

### BRIEF DESCRIPTION OF THE DRAWINGS

The above and other aspects, features, and advantages of certain embodiments will be more apparent from the following description taken in conjunction with the accompanying drawings, in which:

FIG. 1 is a flowchart illustrating a pattern formation method according to at least one example embodiment;

FIGS. 2A to 2C are cross-sectional side views illustrating a pattern formation method using a hydrophobic developer, according to at least one example embodiment;

FIGS. 3A to 3C are cross-sectional side views illustrating a pattern formation method using a hydrophilic developer, according to at least one example embodiment;

FIGS. 4A to 4E are cross-sectional side views illustrating a patterning structure formation method using a hydrophobic developer, according to at least one example embodiment;

FIGS. 5A to 5E are cross-sectional side views illustrating a patterning structure formation method using a hydrophilic developer, according to at least one example embodiment;

FIGS. 6A to 6E are side cross-sectional views illustrating a method of forming a semiconductor device according to at least one example embodiment;

FIGS. 7A to 7J are graphs showing a change in film thickness after development according to doses of Examples 1-1 to 1-4, 2-1 to 2-4, Comparative Example 1-1, and Comparative Example 2-1; and

FIGS. 8A to 8D are views illustrating surface images of films developed with n-butyl acetate (n-BA) or isopropanol (IPA).

### DETAILED DESCRIPTION

Reference will now be made in detail to embodiments, examples of which are illustrated in the accompanying drawings, wherein like reference numerals refer to like elements throughout.

In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Since the present disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.” Additionally, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly. Singular forms may include plural forms unless apparently indicated otherwise contextually. In case that a portion is referred to as “comprises” a component, the portion may not exclude another component but may further include another component unless stated otherwise.

An expression used in the singular encompasses the expression of the plural unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cₓ-C_{y}” means that the number of carbon atoms constituting a substituent is in a range of x to y. For example, “C₁-C₆” means that the number of carbon atoms constituting a substituent is in a range of 1 to 6, and “C₆-C₂₀” means that the number of carbon atoms constituting a substituent is in a range of 6 to 20.

As used herein, the term “monovalent hydrocarbon group” may refer to a monovalent residue derived from an organic compound including carbon and hydrogen or a derivative thereof, and specific examples thereof may include: linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); monovalent saturated cycloaliphatic hydrocarbon groups (cycloalkyl groups) (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (alkenyl group or alkynyl group) (for example, an allyl group); a monovalent unsaturated cycloaliphatic hydrocarbon group (cycloalkenyl group) (for example, 3-cyclohexenyl); aryl groups (for example, a phenyl group, a 1-naphthyl group, and a 2-naphthyl group); arylalkyl groups (for example, a benzyl group and a diphenylmethyl group); heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group); or any combination thereof. In addition, in these groups, some hydrogen atoms may be substituted by a moiety including a heteroatom such as oxygen, sulfur, nitrogen, phosphorus, or a halogen atom, or some carbon atoms may be substituted by a moiety including a heteroatom such as oxygen, sulfur, nitrogen, or phosphorus so that these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, or the like.

As used herein, the term “divalent hydrocarbon group” is a divalent residue and means that any one hydrogen atom of the monovalent hydrocarbon group is replaced with a binding site with an adjacent atom. The divalent hydrocarbon group may include, for example, a linear or branched alkylene group, a cycloalkylene group, an alkenylene group, an alkynylene group, a cycloalkenylene group, an arylene group, a group in which some carbon atoms thereof are replaced with a heteroatom, or the like.

As used herein, the term “alkyl group” refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, or the like. As used herein, the term “alkylene group” refers to a linear or branched saturated aliphatic hydrocarbon divalent group, and specific examples thereof include a methylene group, an ethylene group, a propylene group, a butylene group, an isobutylene group, or the like.

As used herein, the term “halogenated alkyl group” refers to a group in which one or more hydrogen of an alkyl group are substituted with halogen atom, and specific examples thereof include CF₃ or the like. Here, a halogen atom is F, Cl, Br, or I.

As used herein, the term “alkoxy group” refers to a monovalent group having a formula of —OA₁₀₁, wherein A₁₀₁ is an alkyl group. Specific examples thereof include a methoxy group, an ethoxy group, an isopropyloxy group, or the like.

As used herein, the term “alkylthio group” refers to a monovalent group having a formula of —SA₁₀₁, wherein A₁₀₁ is an alkyl group.

As used herein, the term “halogenated alkoxy group” refers to a group in which one or more hydrogen atoms of an alkoxy group are substituted with halogen atom, and specific examples thereof include —OCF₃ or the like.

As used herein, the term “halogenated alkylthio group” refers to a group in which one or more hydrogen atoms of an alkylthio group are substituted with halogen atom, and specific examples thereof include —SCF₃ or the like.

As used herein, the term “cycloalkyl group” refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. As used herein, the term “cycloalkylene group” refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, or the like.

As used herein, the term “cycloalkoxy group” refers to a monovalent group having a formula of —OA₁₀₂, wherein A₁₀₂ is a cycloalkyl group. Specific examples thereof include a cyclopropoxy group, a cyclobutoxy group, or the like.

As used herein, the term “cycloalkylthio group” refers to a monovalent group having a formula of —SA₁₀₂, wherein A₁₀₂ is a cycloalkyl group.

As used herein, the term “heterocycloalkyl group” may be a group in which some carbon atoms of the cycloalkyl group are replaced by a moiety including a heteroatom, for example, oxygen, sulfur, or nitrogen, and specifically, the heterocycloalkyl group may include an ether bond, an ester bond, a sulfonate ester bond, carbonate, a lactone ring, a sultone ring, or a carboxylic anhydride moiety. As used herein, the term “heterocycloalkylene group” is a group in which some carbon atoms of the cycloalkylene group are replaced by a moiety including a heteroatom, for example, oxygen, sulfur, or nitrogen.

As used herein, the term “heterocycloalkoxy group” refers to a monovalent group having a formula of —OA₁₀₃, wherein A₁₀₃ is a heterocycloalkyl group.

As used herein, the term “heterocycloalkylthio group” refers to a monovalent group having a chemical formula of —SA₁₀₃, wherein A₁₀₃ is a heterocycloalkyl group.

As used herein, the term “alkenyl group” refers to a linear or branched unsaturated aliphatic hydrocarbon monovalent group including one or more carbon-carbon double bonds. As used herein, the term “alkenylene group” refers to a linear or branched unsaturated aliphatic hydrocarbon divalent group including one or more carbon-carbon double bonds.

As used herein, the term “cycloalkenyl group” refers to a monovalent unsaturated hydrocarbon cyclic group including one or more carbon-carbon double bonds. As used herein, the term “cycloalkenylene group” refers to a divalent unsaturated hydrocarbon cyclic group including one or more carbon-carbon double bonds.

As used herein, the term “heterocycloalkenyl group” is a group in which some carbon atoms of the cycloalkenyl group are replaced by a moiety including a heteroatom, for example, oxygen, sulfur, or nitrogen. As used herein, the term “heterocycloalkenylene group” is a group in which some carbon atoms of the cycloalkenylene group are replaced by a moiety including a heteroatom, for example, oxygen, sulfur, or nitrogen.

As used herein, the term “alkynyl group” refers to a linear or branched unsaturated aliphatic hydrocarbon monovalent group including one or more carbon-carbon triple bonds.

As used herein, the term “aryl group” refers to a monovalent group having a carbocyclic aromatic system, and specific examples thereof include a phenyl group, a naphthyl group, an anthracenyl group, a phenanthrenyl group, a pyrenyl group, a chrysenyl group, or the like. As used herein, the term “arylene group” refers to a divalent group having a carbocyclic aromatic system.

As used herein, the term “aryloxy group” refers to a monovalent group having a chemical formula of —OA₁₀₄, wherein A₁₀₄ is an aryl group.

As used herein, the term “arylthio group” refers to a monovalent group having a chemical formula of —SA₁₀₄, wherein A₁₀₄ is an aryl group.

As used herein, the term “heteroaryl group” refers to a monovalent group having a heterocyclic aromatic system, and specific examples thereof include a pyridinyl group, a pyrimidinyl group, a pyrazinyl group, or the like. As used herein, the term “heteroarylene group” refers to a divalent group having a heterocyclic aromatic system.

As used herein, the term “heteroaryloxy group” refers to a monovalent group having a chemical formula of —OA₁₀₅, wherein A₁₀₅ is a heteroaryl group.

As used herein, the term “heteroarylthio group” refers to a monovalent group having a chemical formula of —SA₁₀₅, wherein A₁₀₅ is a heteroaryl group.

As used herein, the term “arylalkyl group” refers to a group in which a monovalent group having a carbocyclic aromatic system is substituted for an alkyl group, and specific examples thereof include a benzyl group, a diphenylmethyl group, or the like.

As used herein, the term “heteroarylalkyl group” refers to a group in which a monovalent group having a heterocyclic aromatic system is substituted for an alkyl group.

In this specification, the term “heterocyclic group” refers to a C₁-C₆₀ monocyclic or polycyclic group including at least one heteroatom and is a group including all of monovalent, divalent, and trivalent groups.

As used herein, the term “substituent” includes: deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; A C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof; or any combination thereof.

Hereinafter, some example embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Resist Composition]

A pattern formation method according to embodiments may include:
1) forming a resist film by applying a resist composition including an organometallic compound represented by Formula 1 below and an additive represented by Formula 2 below,
2) forming an exposed portion and an unexposed portion by exposing at least a portion of the resist film to high-energy rays, and
3) developing the exposed resist film by using a developer,
wherein: i) the developer is a hydrophobic developer, and the unexposed portion is removed in the developing; or
ii) the developer is a hydrophilic developer, and the exposed portion is removed in the developing:

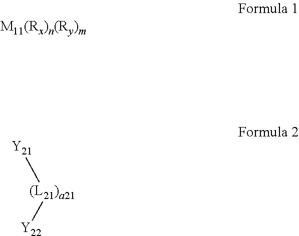

wherein, in Formulas 1 and 2,
M₁₁ is at least one of indium (In), tin (Sn), antimony (Sb), tellurium (Te), thallium (Tl), lead (Pb), bismuth (Bi), or polonium (Po),
Rₓ is *—X₁—Y₁,
R_{y} is *-(L₁)ₐ₁-(R₁)_{b1},
n is an integer from 0 to 6,
m is an integer from 1 to 6,
m+n is 6 or less,
a plurality of Rₓ are identical to or different from each other,
a plurality of R_{y} are identical to or different from each other,
X₁ is at least one of O, OC(═O), C(═O)O, OS(═O), S(═O)O, OS(═O)₂, S(═O)₂O, S, SC(═O), or C(═O)S,
Y₁ is at least one of hydrogen, deuterium, or a linear, branched, or cyclic C₁-C₃₀ monovalent hydrocarbon group optionally containing a heteroatom,
L₁ is a linear, branched, or cyclic C₁-C₃₀ divalent hydrocarbon group optionally containing a heteroatom,
a1 is an integer from 0 to 4,
R₁ is a linear, branched, or cyclic C₁-C₃₀ monovalent hydrocarbon group optionally containing a heteroatom, wherein two adjacent groups in a plurality of R₁ are optionally bonded to each other to form a condensed ring,
b1 is an integer from 1 to 4,
Y₂₁ and Y₂₂ are each independently a linear, branched, or cyclic C₁-C₃₀ divalent hydrocarbon group including one or more selected from an oxygen atom, a sulfur atom, a nitrogen atom, and a phosphorus atom as a heteroatom,
L₂₁ is a single bond, a double bond, or a linear, branched, or cyclic C₁-C₃₀ divalent hydrocarbon group,
each a21 is independently an integer from 1 to 4, and
adjacent two of Y₂₁, Y₂₂, and L₂₁ are optionally bonded to each other to form a condensed ring.

### <Organometallic Compound>

The organometallic compound may have a molecular weight of about 3,000 g/mol or less. Specifically, the organometallic compound may have a molecular weight of about 2,000 g/mol or less.

For example, in Formula 1, M₁₁ may be Sn, Sb, Te, or Bi. Specifically, in Formula 1, M₁₁ may be Sn.

In Formula 1, m+n may denote a valence of Mr.

For example, in Formula 1, n may be an integer from 1 to 4.

For example, in Formula 1, m may be an integer from 1 to 4.

In at least one example embodiment, in Formula 1, n may be an integer from 1 to 4, m may be an integer from 1 to 4, and M₁₁ may be Sn.

For example, in Formula 1, a bond between M₁₁ and Rₓ may be an M₁₁-oxygen single bond or an M₁₁-sulfur single bond. Specifically, in Formula 1, the bond between Mn and Rₓ may be an M₁₁-oxygen single bond.

Specifically, in Formula 1, the bond between M₁₁ and R_{y} may be an M₁₁-carbon single bond.

For example, in Formula 1, X₁ may be O, OC(═O), C(═O)O, S, SC(═O), or C(═O)S.

Specifically, in Formula 1, X₁ may be OC(═O) or C(═O)O.

For example, in Formula 1, Y₁ may be hydrogen, deuterium, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group.

Specifically, in Formula 1, Y₁ may be selected from: hydrogen; deuterium; and a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 1, Y₁ may be selected from: hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In particular, in Formula 1, Y₁ may be selected from: hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In at least one embodiment, in Formula 1, Y₁ may be selected from: hydrogen; deuterium; and Formulas 3-1 to 3-38 below:

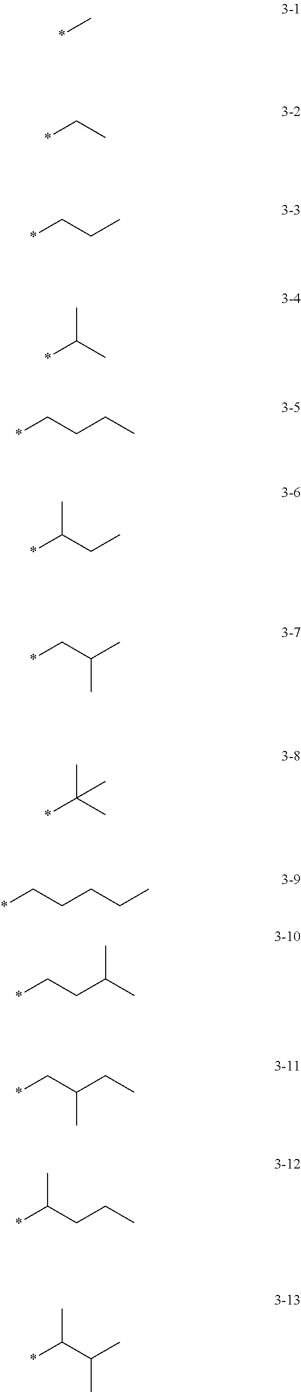

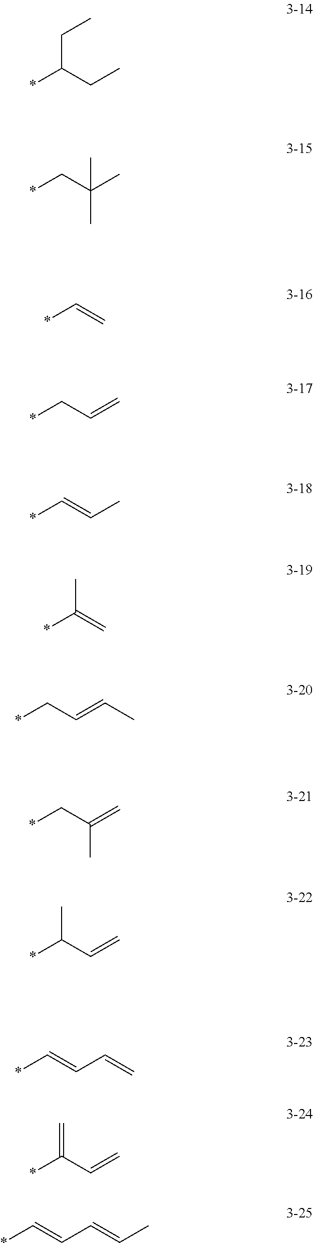

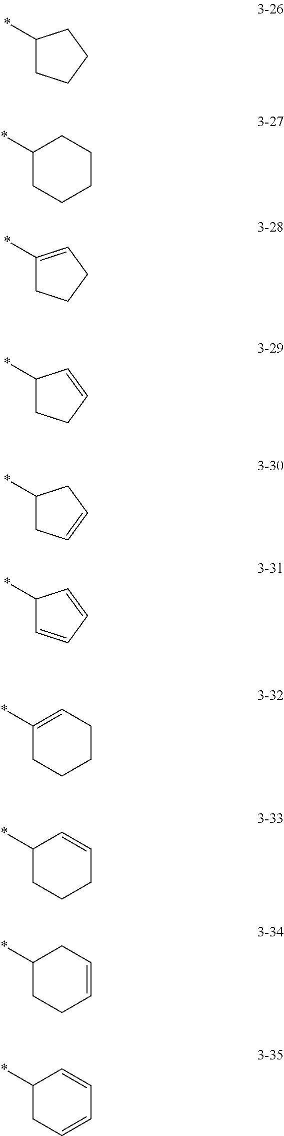

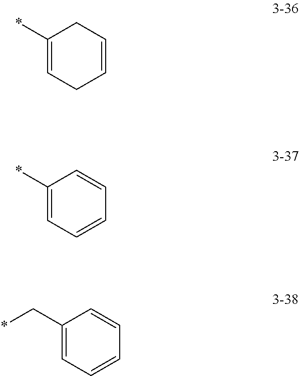 [SMILES: *C1=CCC=CC1 ; *c1ccccc1 ; *Cc1ccccc1]

In Formulas 3-1 to 3-38, * represents a binding site with an adjacent atom, and at least one hydrogen may be optionally substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

For example, in Formula 1, L₁ may be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

Specifically, in Formula 1, L₁ may be selected from: a single bond; and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 1, L₁ may be selected from: a single bond; and a C₁-C₃₀ alkylene group and a C₆-C₃₀ arylene group, each unsubstituted or substituted with deuterium, a halogen, a hydroxyl group, a cyano group, a C₁-C₂₀ alkyl group, a C₁-C₂₀ halogenated alkyl group, or any combination thereof.

In Formula 1, a1 may denote the number of repetitions of Lᵢ.

For example, in Formula 1, a1 may be 0, 1, or 2.

In at least one example embodiment, in Formula 1, (L₁)ₐ₁ may be selected from: a single bond; or Formulas 5-1 to 5-7 below:

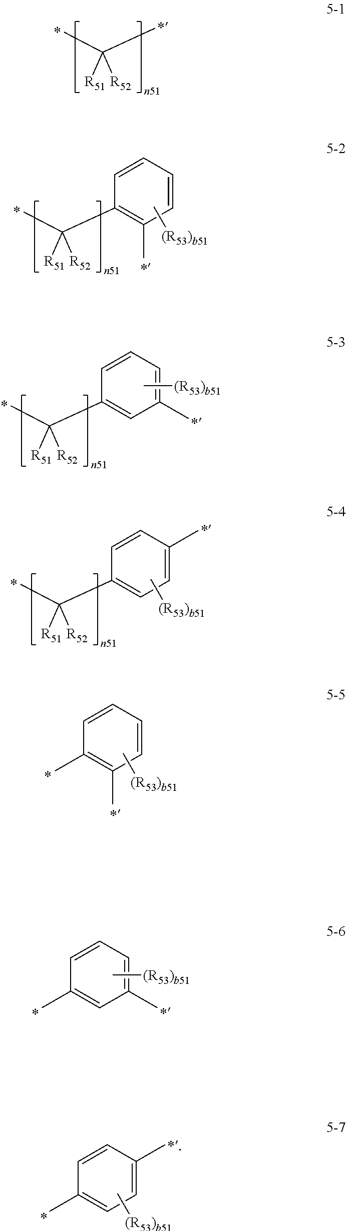

In Formulas 5-1 to 5-7,
R₅₁ to R₅₃ may each independently be hydrogen, deuterium, a halogen, a hydroxyl group, a cyano group, a C₁-C₄ alkyl group, or a C₁-C₄ halogenated alkyl group,
b51 may be an integer from 1 to 4,
n51 may be an integer from 1 to 4, and
* and *′ may each be a binding site with an adjacent atom.

For example, in Formula 1, R₁ may be a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group.

Specifically, in Formula 1, R₁ may be selected from a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 1, R₁ may be selected from a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In particular, in Formula 1, R₁ may be selected from a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In at least one example embodiment, in Formula 1, R₁ may be selected from Formulas 3-1 to 3-38 below:

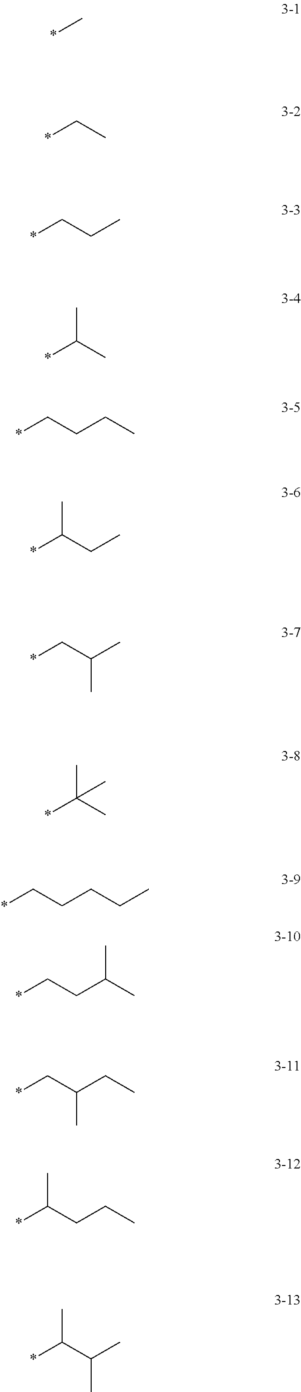

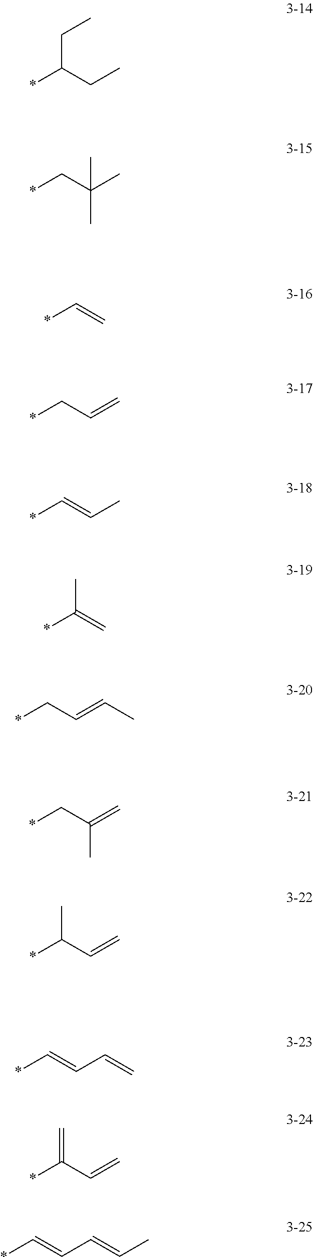

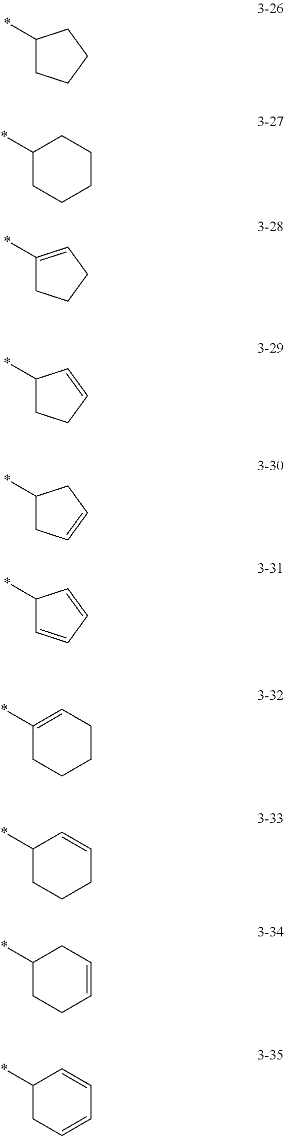

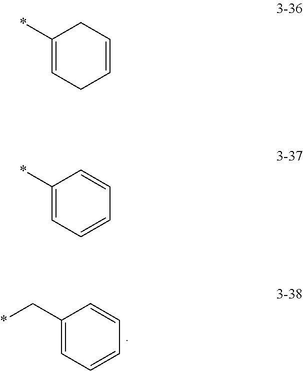 [SMILES: *C1=CCC=CC1 ; *c1ccccc1 ; *Cc1ccccc1]

In Formulas 3-1 to 3-38, * represents a binding site with an adjacent atom, and at least one hydrogen may be optionally substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In Formula 1, b1 may denote the number of substitutions of R₁.

For example, in Formula 1, b1 may be 1 or 2.

In at least one example embodiment, adjacent two of R₁ may be optionally bonded to each other to form a condensed ring.

In at least one example embodiment, in Formula 1, b1 may be 2 or more, and R₁ may be selected from a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In at least one example embodiment, the organometallic compound represented by Formula 1 may be represented by at least one of Formulas 1-1 to 1-4 below:

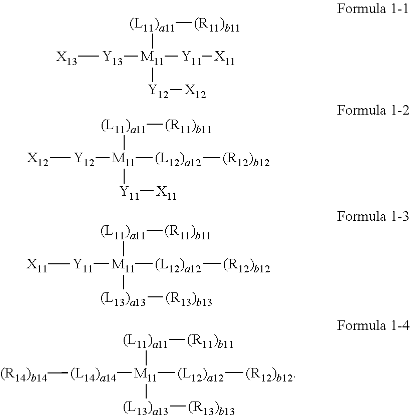

In Formulas 1-1 to 1-4,
M₁₁ may be as described above,
L₁₁ to L₁₄ may each independently be defined as for L₁ in Formula 1,
a11 to a14 may each independently be defined as for a1 in Formula 1,
R₁₁ to R₁₄ may each independently be defined as for R₁ in Formula 1,
b11 to b14 may each independently be defined as for b1 in Formula 1,
X₁₁ to X₁₃ may each independently be defined as for X₁ in Formula 1, and
Y₁₁ to Y₁₃ may each independently be defined as for Y₁ in Formula 1.

In at least one example embodiment, the organometallic compound represented by Formula 1 may be selected from Group I below:

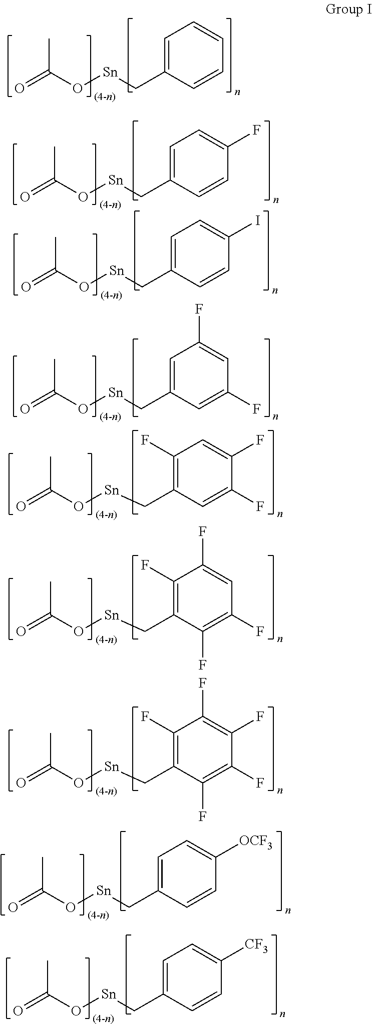

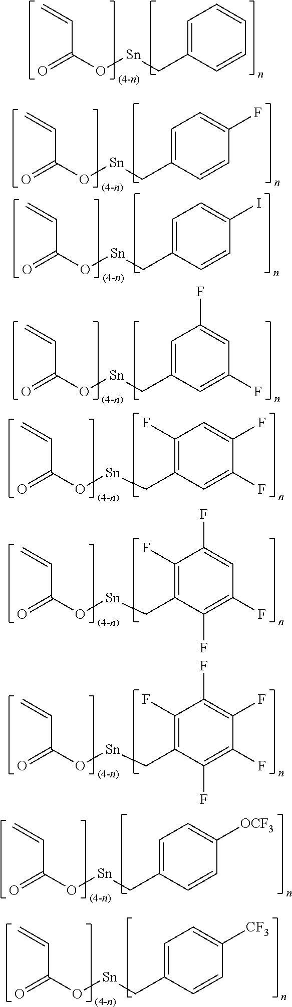

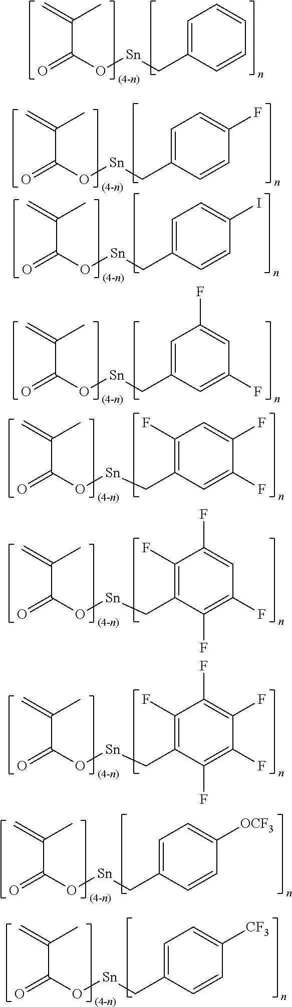

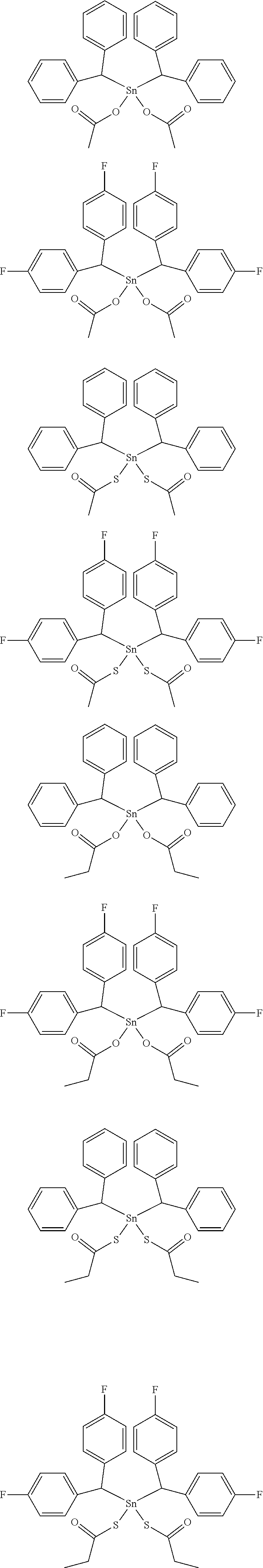

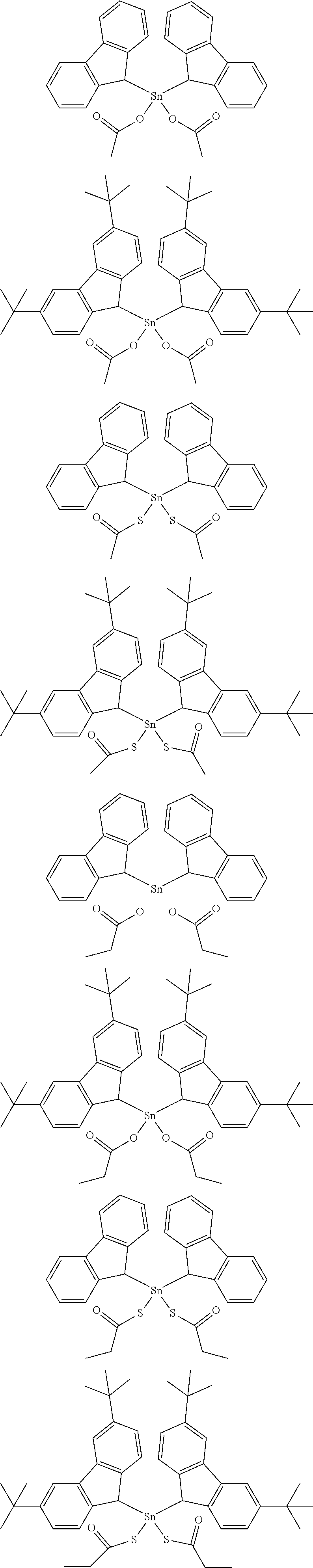

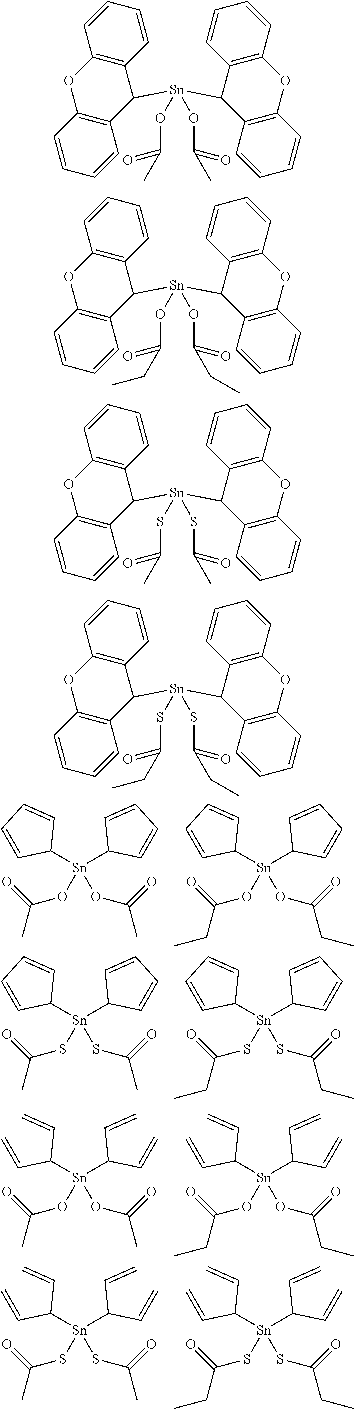

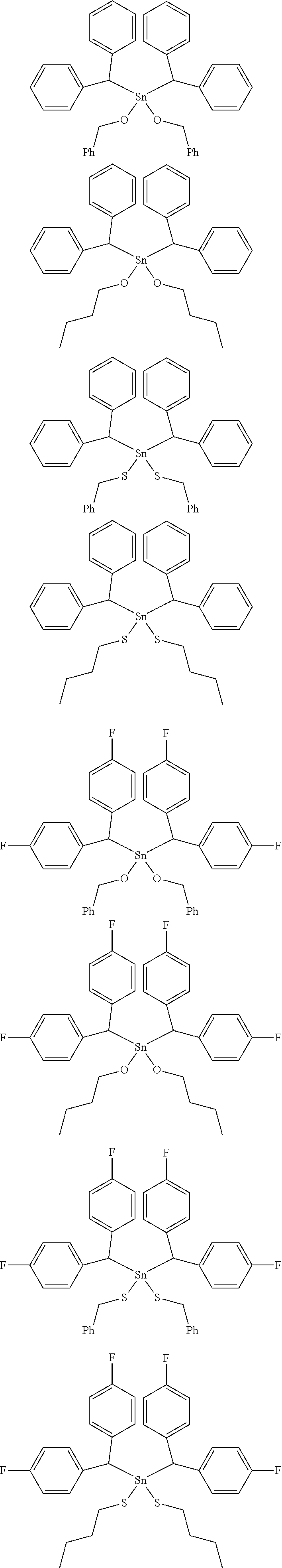

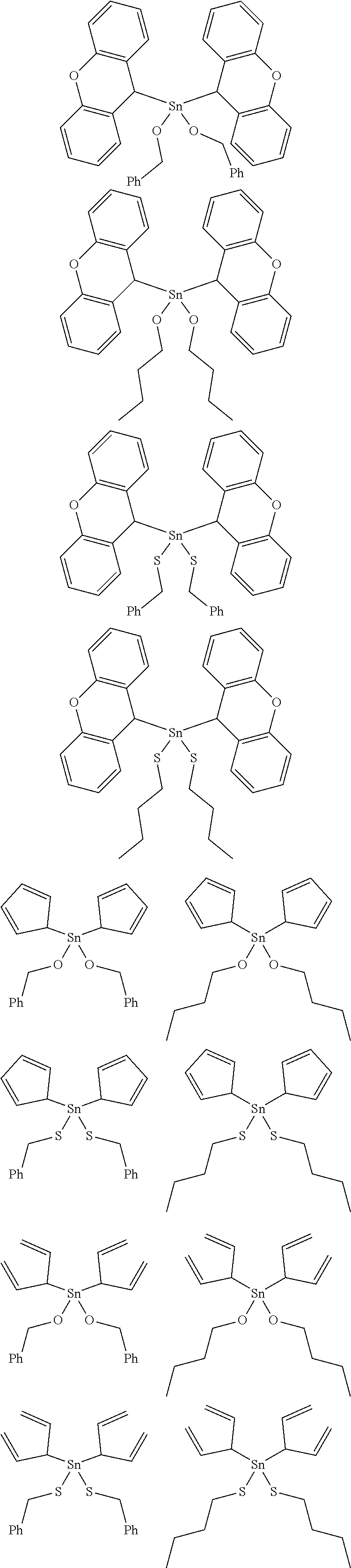

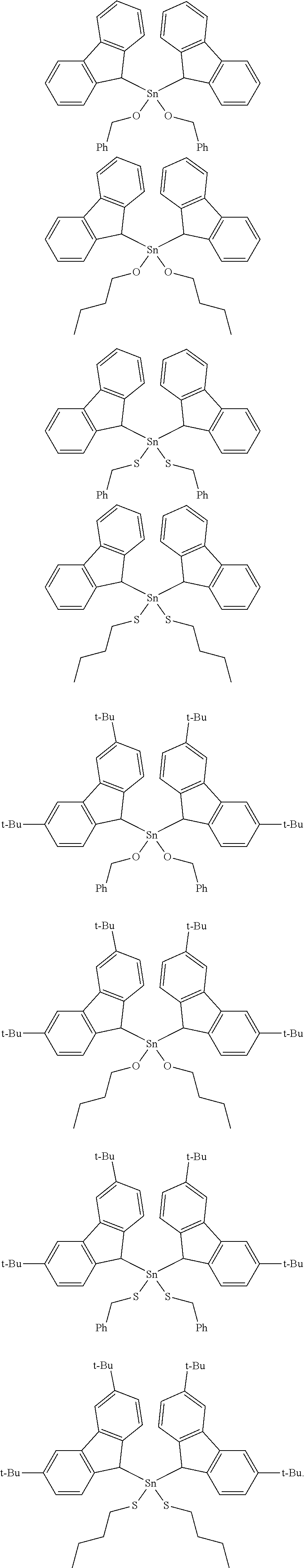

In Group I, n may be an integer from 1 to 4.

For example, in Group I, n may be 2.

The organometallic compound may be any one type represented by Formula 1, or two or more types of organometallic compounds may be mixed and used.

In the resist composition, the organometallic compound may be included in an amount of about 0.01 parts by weight to about 99.99 parts by weight, specifically, in an amount of 0.2 parts by weight or more, 0.5 parts by weight or more, 1 part by weight or more, 1.5 parts by weight or more, 90 parts by weight or less, or 80 parts by weight or less, with respect to 100 parts by weight of the resist composition. When the above range is satisfied, while a chemical bond between organometallic compounds is sufficiently formed, side reactions may be suppressed, thereby providing a resist composition with improved sensitivity and/or resolution.

### <Additives>

For example, in Formula 2, Y₂₁ may be represented by at least one of Formulas 4-1 to 4-5 below, and Y₂₂ may be represented by at least one of Formulas 4-6 to 4-10 below:

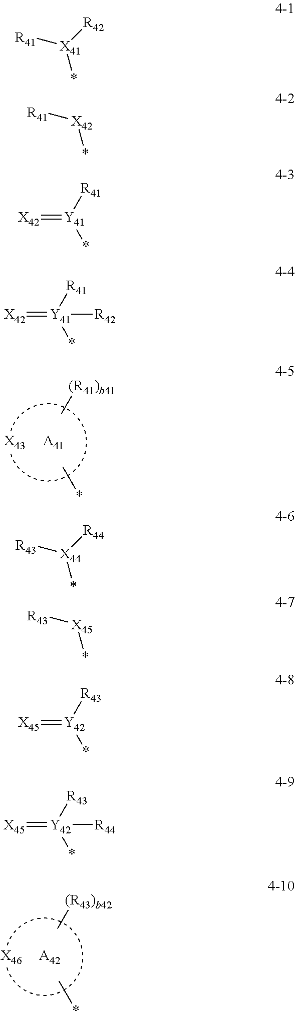

In Formulas 4-1 to 4-10,
X₄₁ and X₄₄ may each independently be N or P,
X₄₂ and X₄₅ may each independently be O or S,
X₄₃ and X₄₆ may each independently be O, S, N, or P,
Y₄₁ and Y₄₂ may each independently be C, S, or P,
A₄₁ may be a C₁-C₃₀ heterocyclic group including X₄₃ as a ring member,
A₄₂ may be a C₁-C₃₀ heterocyclic group including X₄₆ as a ring member,
R₄₁ to R₄₄ may each independently be hydrogen, deuterium, a halogen, a cyano group, a nitro group, a hydroxyl group, a thiol group, an amino group, a carboxylate group, or a linear, branched, or cyclic C₁-C₃₀ divalent hydrocarbon group,
b41 and b42 may each independently be an integer from 1 to 10, and
* may be a binding site with an adjacent atom.

In at least one example embodiment, the additive may include a structure in which at least one selected from X₄₁ to X₄₃ and at least one selected from X₄₄ to X₄₆ are coordinated to a metal atom, for example, M₁₁, to form a 5-, 6-, or 7-membered ring.

For example, in Formulas 4-5 and 4-10, A₄₁ and A₄₂ may each independently be i) a monovalent group derived from a first ring, ii) a monovalent group derived from a condensed ring in which two or more first rings are condensed with each other, or iii) a monovalent group derived from a condensed ring in which one or more first rings and one or more second rings are condensed with each other.

The first ring may be tetrahydropyrane, dihydropyrane, pyrane, tetrahydrothiopyrane, dihydrothiopyrane, thiopyrane, tetrahydrofurane, dihydrofurane, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine, or triazine.

The second ring may be cyclopentane, cyclopentadiene, cyclohexane, cyclohexene, cyclohexadiene, benzene, or naphthalene.

Specifically, in Formulas 4-5 and 4-10, A₄₁ and A₄₂ may each independently be i) a monovalent group derived from a first ring, ii) a monovalent group derived from a condensed ring in which two or more first rings are condensed with each other, or iii) a monovalent group derived from a condensed ring in which one or more first rings and one or more second rings are condensed with each other.

The first ring may be tetrahydropyrane, dihydropyrane, pyrane, tetrahydrothiopyrane, dihydrothiopyrane, thiopyrane, tetrahydrofurane, dihydrofurane, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine, or triazine.

The second ring may be benzene.

For example, in Formulas 4-1 to 4-10, R₄₁ to R₄₄ may each independently be selected from: hydrogen; deuterium; a halogen; a cyano group; a nitro group; a hydroxyl group; a thiol group; an amino group; a carboxylate group; and a C₁-C₃₀ alkyl group, a C₁-C₃₀ halogenated alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

Specifically, in Formulas 4-1 to 4-10, R₄₁ to R₄₄ may each independently be selected from: hydrogen; deuterium; a halogen; a cyano group; a nitro group; a hydroxyl group; a thiol group; an amino group; a carboxylate group; and a C₁-C₃₀ alkyl group, a C₁-C₃₀ halogenated alkyl group, a C₃-C₃₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a C₁-C₂₀ alkyl group, a C₁-C₂₀ halogenated alkyl group, a C₃-C₂₀ cycloalkyl group, a C₆-C₃₀ aryl group, or any combination thereof.

In at least one example embodiment, in Formula 2, i) Y₂₁ may be represented by Formula 4-5, and Y₂₂ may be represented by any one of Formulas 4-6 to 4-10; or ii) Y₂₁ may be represented by any one of Formulas 4-1 to 4-5, and Y₂₂ may be represented by Formula 4-10.

In at least one example embodiment, in Formula 2, Y₂₁ may be represented by Formula 4-5, and Y₂₂ may be represented by Formula 4-10.

For example, in Formula 2, L₂₁ may be a single bond, a double bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

Specifically, in Formula 2, L₂₁ may be selected from: a single bond; a double bond; and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 2, L₂₁ may be selected from: a single bond; a double bond; and a C₁-C₃₀ alkylene group and a C₂-C₃₀ alkenylene group, each unsubstituted or substituted with deuterium, a halogen, a hydroxyl group, a cyano group, a C₁-C₂₀ alkyl group, a C₁-C₂₀ halogenated alkyl group, or any combination thereof.

In at least one example embodiment, the additive may be represented by Formula 2-1 below:

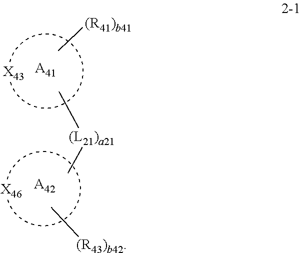

In Formula 2-1, X₄₃, X₄₆, A₄₁, A₄₂, L₂₁, a21, R₄₁, R₄₃, b41, and b42 may be defined as described above.

In at least one example embodiment, the additive may be represented by at least one of Formula 2-11 below or Formula 2-12 below:

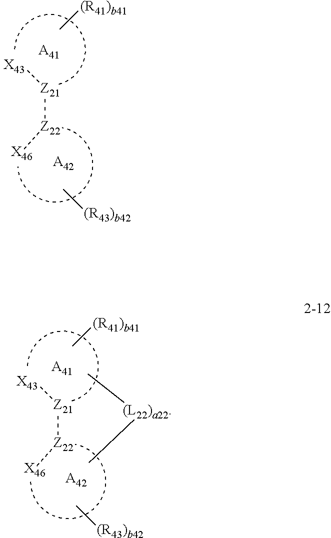

In Formulas 2-11 and 2-12,
X₄₃ and X₄₆ may each independently be O, S, N, or P,
A₄₁ may be a C₁-C₃₀ heterocyclic group including X₄₃ as a ring member,
A₄₂ may be a C₁-C₃₀ heterocyclic group including X₄₆ as a ring member,
Z₂₁ and Z₂₂ may each independently be C or N,
a bond between Z₂₁ and Z₂₂ may be a single bond or a double bond,
L₂₂ may be selected from: a single bond; a double bond; and a C₁-C₃₀ alkylene group and a C₂-C₃₀ alkenylene group, each unsubstituted or substituted with deuterium, a halogen, a hydroxyl group, a cyano group, a C₁-C₂₀ alkyl group, a C₁-C₂₀ halogenated alkyl group, or any combination thereof,
a22 may be an integer from 1 to 4,
R₄₁ and R₄₃ may each independently be a linear, branched, or cyclic C₁-C₃₀ divalent hydrocarbon group, and
b41 and b42 may each independently be an integer from 1 to 10.

In Formulas 2-11 and 2-12, a bond between X₄₃ and Z₂₁ and a bond between Z₂₂ and X₄₆ may each independently be a single bond or a double bond.

For example, in Formulas 2-11 and 2-12, three chemical bonds may be present between X₄₃ and X₄₆, and the three chemical bonds may include a chemical bond between X₄₃ and Z₂₁, a chemical bond between Z₂₁ and Z₂₂, and a chemical bond between Z₂₂ and X₄₆.

In at least one example embodiment, the additive may be represented by at least one of Formulas 2-21 to 2-26 below:

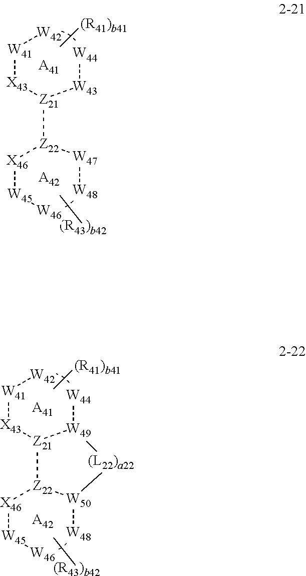

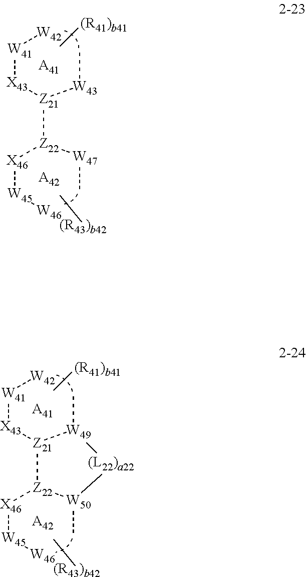

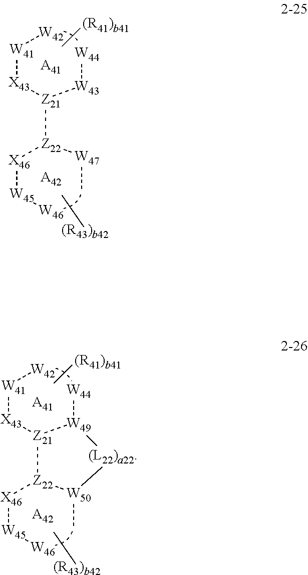

In Formulas 2-21 to 2-26,
X₄₃ and X₄₆ may each independently be O, S, N, or P,
A₄₁ may be a C₁-C₃₀ heterocyclic group including Z₂₁, X₄₃, W₄₁ to W₄₄, and W₄₉ as ring members,
A₄₂ may be a C₁-C₃₀ heterocyclic group including Z₂₂, X₄₆, W₄₅ to W₄₈, and W₅₀ as ring members,
Z₂₁ and Z₂₂ may each independently be C or N,
W₄₁ to W₅₀ may each independently be C(R₄₁ₐ), C(R₄₁ₐ)(R_{41b}), C(R₄₃ₐ), C(R₄₃ₐ)(R_{43b}), or N,
a bond between Z₂₁ and Z₂₂, a bond between Z₂₁ and X₄₃, a bond between X₄₃ and W₄₁, a bond between W₄₁ and W₄₂, a bond between Z₂₁ and W₄₃, a bond between W₄₃ and W₄₄, a bond between Z₂₂ and X₄₆, a bond between X₄₆ and W₄₅, a bond between W₄₅ and W₄₆, a bond between Z₂₂ and W₄₇, a bond between W₄₇ and W₄₈, a bond between W₄₄ and W₄₉, a bond between W₄₉ and Z₂₁, a bond between Z₂₂ and W₅₀, a bond between W₄₈ and W₅₀, a bond between W₄₂ and W₄₃, a bond between W₄₆ and W₄₇, a bond between W₄₂ and W₄₉, and a bond between W₄₆ and W₅₀ may each be a single bond or a double bond,
L₂₂ may be selected from: a single bond; a double bond; and a C₁-C₃₀ alkylene group and a C₂-C₃₀ alkenylene group, each unsubstituted or substituted with deuterium, a halogen, a hydroxyl group, a cyano group, a C₁-C₂₀ alkyl group, a C₁-C₂₀ halogenated alkyl group, or any combination thereof,
a22 may be an integer from 1 to 4,
R₄₁, R₄₃, R₄₁ₐ, R_{41b}, R₄₃ₐ, and R_{43b} may each independently be a linear, branched, or cyclic C₁-C₃₀ divalent hydrocarbon group, and
b41 and b42 may each independently be an integer from 1 to 10.

In at least one example embodiment, the additive may be represented by at least one of Formulas 2-31 to 2-48 below:

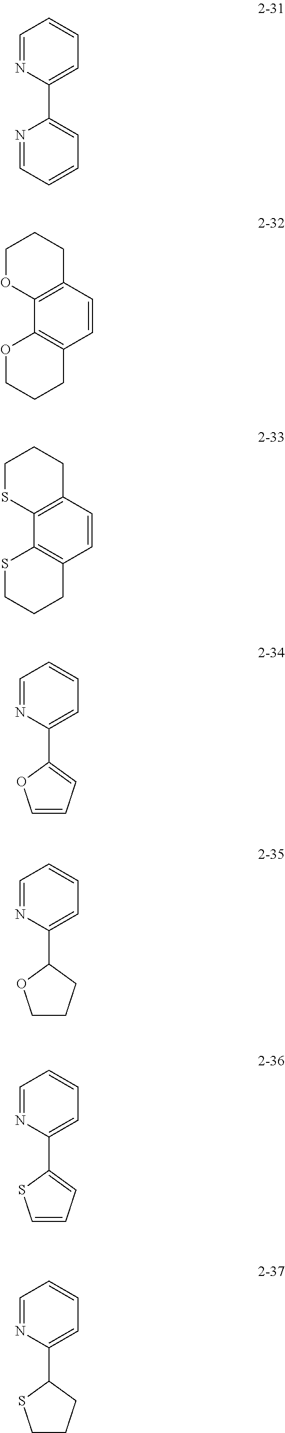

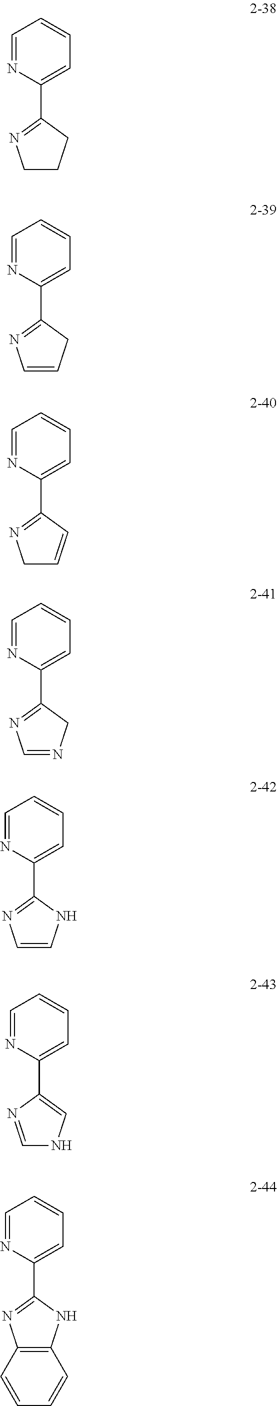

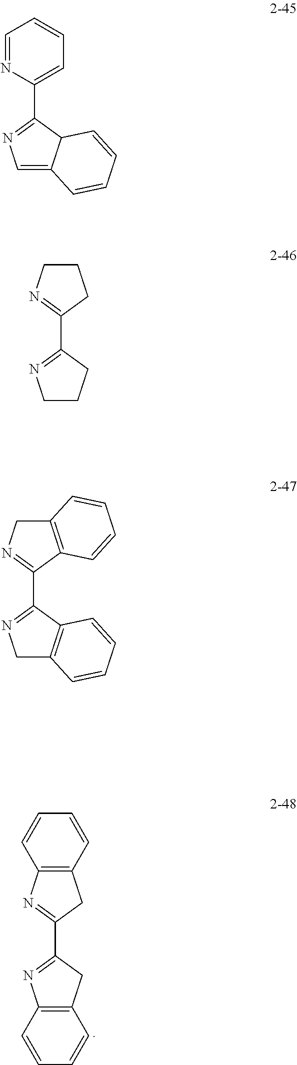 [SMILES: C1=CC2=CN=C(c3ccccn3)C2C=C1 ; C1CN=C(C2=NCCC2)C1 ; c1ccc2c(c1)CN=C2C1=NCc2ccccc21 ; c1ccc2c(c1)CC(C1=Nc3ccccc3C1)=N2]

In Formulas 2-31 to 2-48,
at least one hydrogen may be optionally substituted with deuterium, a halogen, a cyano group, a nitro group, a hydroxyl group, a thiol group, a C₁-C₂₀ alkyl group, a C₁-C₂₀ halogenated alkyl group, a C₃-C₂₀ cycloalkyl group, a C₂-C₂₀ alkenyl group, a C₃-C₂₀ cycloalkenyl group, a C₃-C₂₀ heterocycloalkenyl group, a C₂-C₂₀ alkynyl group, a C₆-C₂₀ aryl group, a C₇-C₂₀ arylalkyl group, a C₁-C₂₀ heteroaryl group, a C₂-C₂₀ heteroarylalkyl group, or any combination thereof, and
at least one carbon and at least one nitrogen may be optionally bonded to an adjacent carbon or nitrogen to form a ring.

In at least one example embodiment, the additive may be selected from Group II below:

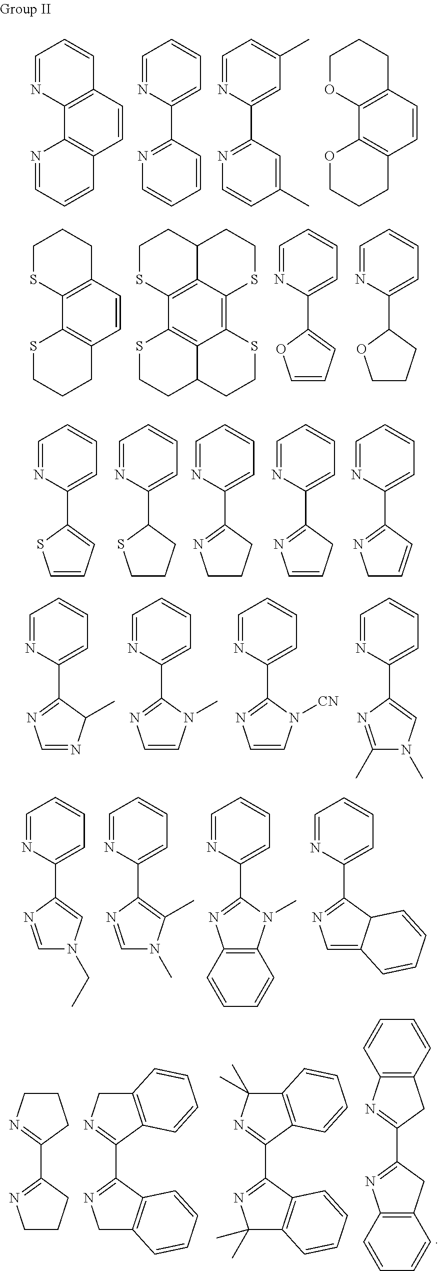

Since the additive includes N, O, S, and/or P providing a lone-pair electron pair, the additive may provide a coordination bond to the organometallic compound, thereby improving the chemical stability of the organometallic compound.

The additive may be one type represented by Formula 2, and/or two or more types of additives may be mixed and used.

In the resist composition, the additive may be included in an amount of about 0.01 parts by weight to about 99.99 parts by weight, specifically, in an amount of 0.2 parts by weight or more, 0.5 parts by weight or more, 1 part by weight or more, 1.5 parts by weight or more, 90 parts by weight or less, or 80 parts by weight or less, with respect to 100 parts by weight of the resist composition. When the above range is satisfied, while a chemical bond between organometallic compounds is sufficiently formed, side reactions may be suppressed, thereby providing a resist composition with improved sensitivity and/or resolution.

In the resist composition, the additive may be included in an amount of about 0.1 parts by weight to about 100,000 parts by weight with respect to 100 parts by weight of the organometallic compound. Specifically, the additive may be included in an amount of about 10 parts by weight to about 1,000 parts by weight with respect to 100 parts by weight of the organometallic compound. When the above range is satisfied, the photosensitivity of the resist composition may be maintained at a level of a resist composition to which an additive is not added, and also storage stability may be significantly improved.

Since the resist composition is non-chemically amplified, the resist composition may not substantially include a photoacid generator. As such, an acid may not be generated from a photoacid generator during development of the resist composition and/or the amount of diffusible acid may be lesser than a comparative example including a photoacid generator, and thereby the reduction in uniformity of patterns and/or the increase in surface roughness resulting from acid diffusion may be protected against.

Since the physical properties of the organometallic compound are changed by exposure to light, the resist composition may not substantially include a compound having a molecular weight of about 1,000 or more other than the organometallic compound.

The solubility of the resist composition in a developer may be changed by exposure to high-energy rays. The resist composition may be a negative-type resist composition in which an unexposed portion of a resist film is dissolved and removed to form a negative-type resist pattern or may be a positive-type resist composition in which an exposed portion is dissolved and removed to form a positive-type resist pattern. The resist composition may be modified in various ways such as being a negative type or a positive type according to a type of a developer.

The structure (composition) of the organometallic compound and the additive may be identified by performing Fourier transform infrared spectroscopy (FT-IR) analysis, nuclear magnetic resonance (NMR) analysis, X-ray fluorescence (XRF) analysis, mass spectrometry, ultraviolet (UV) analysis, single crystal X-ray structure analysis, powder X-ray diffraction (PXRD) analysis, liquid chromatography analysis, size exclusion chromatography (SEC) analysis, thermal analysis, or the like. A detailed identification method is as described in Examples.

### <Solvent>

The resist composition may further include a solvent.

The solvent included in the resist composition is selected from solvents configured to dissolve or disperse the organometallic compound, the additive, and any other components contained in the resist composition. As the solvent, one type of a solvent may be used, or two or more different types of solvents may be used in combination.

The solvent may include, for example, a nonpolar solvent, a polar aprotic solvent, or a combination thereof.

For example, the solvent may be a polar aprotic solvent.

The nonpolar solvent may include an ether-based solvent, a hydrocarbon-based solvent, or any combination thereof.

The polar aprotic solvent may include at least one selected from an ether-based solvent, a ketone-based solvent, an amide-based solvent, an ester-based solvent, a sulfoxide-based solvent, a lactate-based solvent, or any combination thereof.

Examples of the ether-based solvent may include, for example, at least one of a dialkyl ether-based solvent such as diethyl ether, dipropyl ether, dibutyl ether, diethylene glycol dimethyl ether, or dipropylene glycol dimethyl ether; a cyclic ether-based solvent such as 1,4-dioxane, tetrahydrofuran or tetrahydropyran; or an aromatic ring-containing ether-based solvent such as diphenyl ether or anisole.

Examples of the ketone-based solvent may include, for example, at least one of a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone; a cyclic ketone-based solvent such as cyclopentanone, cyclohexanone, cycloheptanone, cyclooctanone, or methylcyclohexanone; or 2,4-pentanedione, acetonyl acetone, and acetophenone.

Examples of the amide-based solvent may include, for example, at least one of a cyclic amide-based solvent such as N,N′-dimethylimidazolidinone or N-methyl-2-pyrrolidone; and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent may include, for example, at least one of an acetate ester-based solvent such as methyl acetate, ethyl acetate, n-propyl acetate, isopropyl acetate, n-butyl acetate (n-BA), isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate; a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, or dipropylene glycol monoethyl ether acetate; a lactone-based solvent such as 7-butyrolactone or 6-valerolactone; a carbonate-based solvent such as dimethyl carbonate, diethyl carbonate, ethylene carbonate, or propylene carbonate; a ethylene glycol diacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, or diethyl phthalate.

Examples of the sulfoxide-based solvent may include dimethyl sulfoxide, diethyl sulfoxide, or the like.

Examples of the lactate-based solvent may include methyl lactate, ethyl lactate (EL), n-butyl lactate, n-amyl lactate, or the like.

Examples of the hydrocarbon-based solvent may include, for example, at least one of an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

Specifically, the solvent may be selected from a lactate-based solvent, a ketone-based solvent, an ester-based solvent, and any combination thereof.

More specifically, the solvent may be selected from methyl lactate, EL, n-butyl lactate, methyl ethyl ketone, cyclopentanone, cyclohexanone, cycloheptanone, PGMEA, 7-butyrolactone, 6-valerolactone, n-BA, and any combination thereof.

The resist composition may not substantially include water, and thus the solvent may not include water. Specifically, the resist composition may include water in an amount of 3 wt % or less, and the solvent may include water in an amount of 3 wt % or less.

The solvent may be included in an amount of about 0 parts by weight to about 99.9 parts by weight with respect to 100 parts by weight of the resist composition. As the organic solvent, one type of an organic solvent may be used, or two or more different types of organic solvents may be mixed and used.

### <Additional Components>

In at least some examples, the resist composition may further include a surfactant, a crosslinking agent, a leveling agent, a colorant, or any combination thereof as necessary.

The resist composition may further include a surfactant to improve coatability, developability, or the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 95 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC-103, Surflon™ SC-104, Surflon™ SC-105, and Surflon™ SC-106 (manufactured by AGC Seimi Chemical Co., Ltd.), or the like.

The surfactant may be included in an amount of about 0 parts by weight to about 20 parts by weight with respect to 100 parts by weight of the resist composition. As the surfactant, one type of a surfactant may be used, or two or more different types of surfactants may be mixed and used.

A method of preparing the resist composition is not particularly limited, and for example, a method of mixing a polymer and any components added as needed in an organic solvent may be used. A temperature or time during mixing is not particularly limited. If necessary, filtration may be performed after mixing.

### [Pattern Formation Method]

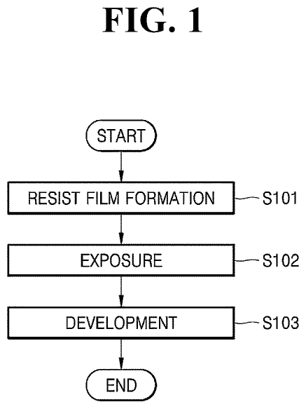

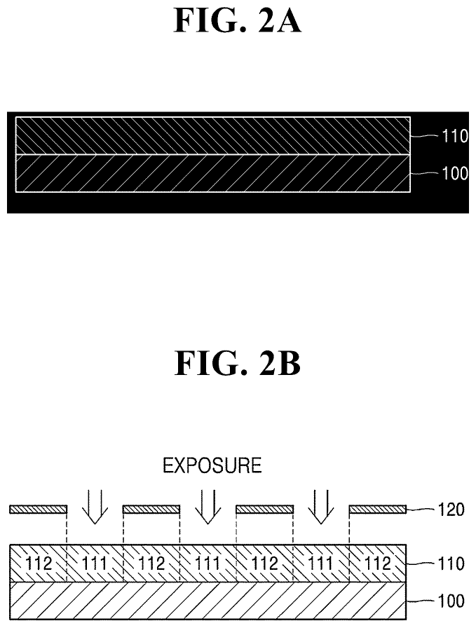

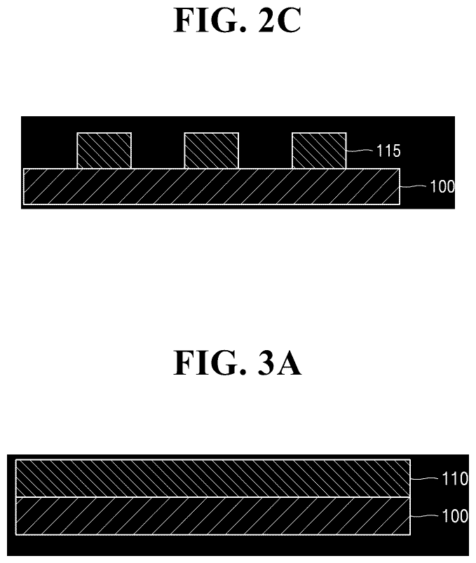

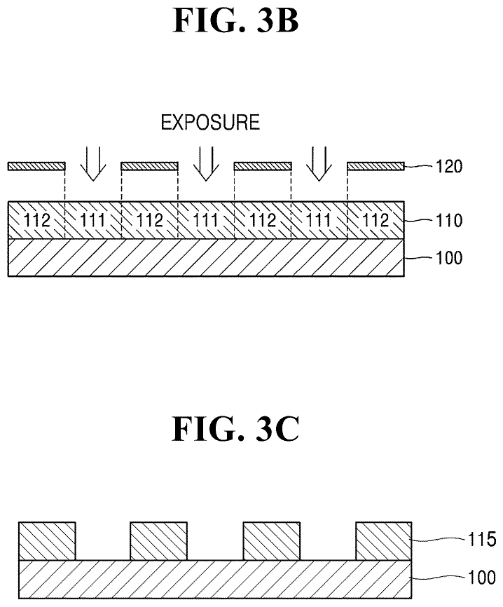

Hereinafter, a pattern formation method according to embodiments will be described in more detail with reference to FIGS. 1 and 2A to 2C. FIG. 1 is a flowchart illustrating a pattern formation method according to embodiments, and FIGS. 2A to 2C 3A to 3C are side cross-sectional views illustrating a pattern formation method according to embodiments. FIGS. 2A to 2C are cross-sectional side views illustrating the pattern formation method using a hydrophobic developer, and FIGS. 3A to 3C are cross-sectional side views illustrating the pattern formation method using a hydrophilic developer.

Referring to FIG. 1, the pattern formation method may include operation S101 of applying a resist composition onto a substrate to form a resist film, operation S102 of exposing at least a portion of the resist film to high-energy rays, and operation S103 of developing the exposed resist film by using a developer. Such operations may be omitted if necessary or may be performed in a different order.

First, a substrate 100 may be prepared. The substrate 100 may include, for example, at least one of a semiconductor substrate (such as a silicon substrate or a germanium substrate), glass, quartz, ceramic, copper or the like. In some embodiments, the substrate 100 may include a Group III-V compound such as GaP, GaAs, or GaSb.

The resist composition may be applied to a desired thickness onto the substrate 100, specifically, through a coating method, to form a resist film 110. If necessary, post application bake (PAB) may be performed to remove an organic solvent remaining in the resist film 110.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. Specifically, the resist film 110 may have a thickness of about 10 nanometers (nm) to about 300 nm. More specifically, the resist film 110 may have a thickness of about 30 nm to about 200 nm.

A temperature of the PAB may be 60° C. or more, specifically, 80° C. or more. In addition, the temperature of the PAB may be 150° C. or less, specifically, 140° C. or less. A time of the PAB may be 5 seconds or more, specifically, 10 seconds or more. The time of the PAB may be 600 seconds or less, specifically, 300 seconds or less.

Before the resist composition is applied onto the substrate 100, an etching target film (not shown) may be further formed on the substrate 100. The etching target film may refer to a layer on which an image is transferred from a resist pattern and converted into a certain pattern. In at least one example embodiment, the etching target film (not illustrated) may be formed to include, for example, an insulating material such as silicon oxide, silicon nitride, or silicon oxynitride. In some embodiments, the etching target film may be formed to include a conductive material such as a metal, a metal nitride, a metal silicide, or a metal silicide nitride. In some embodiments, the etching target film may be formed to include a semiconductor material such as polysilicon.

In at least one example embodiment, an antireflection film (not illustrated) may be further formed on the substrate 100 to increase or maximize the efficiency of a resist. The antireflection film may be an organic or inorganic antireflection film.

In at least one example embodiment, a protective film (not shown) may be further provided on the resist film 110 to reduce the influence of alkaline impurities or the like included during a process. In addition, when immersion exposure is performed, for example, a protective film for immersion may also be installed on the resist film 110 to avoid direct contact between an immersion medium and the resist film 110.

Next, at least a portion of the resist film 110 may be exposed to high-energy rays. For example, high-energy rays passing through a mask 120 may be irradiated onto at least a portion of the resist film 110. Thus, the resist film 110 may have an exposed portion 111 and an unexposed portion 112.

Although not limited to a specific theory, radicals may be generated in the exposed portion 111 through exposure, which may form cross-links between organometallic compounds, but at the same time, since an additive may inhibit the formation of cross-links between the organometallic compounds, only the polarity of a surface of a film may be changed. Next, when the film is developed, both positive-type and negative-type patterns may be obtained according to the hydrophilicity of a developer.

The exposed portion 111 and the unexposed portion 112 may have different water contact angles, and a difference between the water contact angle of the unexposed portion 112 and the water contact angle of the exposed portion 111 may be 100 or more, specifically, 150 or more.

In at least one example embodiment, an exposure dose of the exposure may be 100 mJ/cm² or less, specifically, 80 mJ/cm² or less, more specifically, 60 mJ/cm² or less, or in particular, 50 mJ/cm² or less, and the difference between the water contact angle of the unexposed portion 112 and the water contact angle of the exposed portion 111 may be 100 or more, specifically, 150 or more.

In some cases, the exposure may be performed by irradiating high-energy rays through a mask with a certain pattern by using a liquid such as water as a medium. Examples of the high-energy rays may include electromagnetic waves such as UV rays, deep ultraviolet (DUV) rays, extreme ultraviolet (EUV) rays (with a wavelength of 13.5 nm), X-rays, and γ-rays; and charged particle beams such as electron beams (EBs) and a rays. Irradiating the high-energy rays may be collectively referred to as “exposure.”

Examples of an exposure light source may include various light sources such as a light source that emits laser light in a UV region, such as a KrF excimer laser (with a wavelength of 248 nm), an ArF excimer laser (with a wavelength of 193 nm), or an F₂ excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of high-energy rays, for example, when EUV rays are used as the high-energy rays, the integral dose may be 2,000 millijoules per centimeters squared (mJ/cm²) or less, specifically, 500 mJ/cm² or less. In addition, when EBs are used as the high-energy rays, the integral dose may be 5,000 microcoulombs per centimeters squared (μC/cm²) or less, specifically, 1,000 μC/cm² or less.

In addition, post exposure bake (PEB) may be performed. A lower limit of a temperature of the PEB may be 50° C. or more, specifically, 80° C. or more. An upper limit of the temperature of the PEB may be 250° C. or less, specifically, 200° C. or less. A lower limit of a time of the PEB may be 5 seconds or more, specifically, 10 seconds or more. An upper limit of the time of the PEB may be 600 seconds or less, specifically, 300 seconds or less.

Next, the exposed resist film 110 may be developed by using a developer to form a resist pattern 115.

As a developer, a hydrophilic developer or a hydrophobic developer may be used. Examples of a developing method may include a dipping method, a puddle method, a spray method, a dynamic injection method, or the like. A developing temperature may be, for example, in a range of about 5° C. to about 60° C., and a developing time may be, for example, in a range of about 5 seconds to about 300 seconds.

In at least some examples, the hydrophobic developer may have a Hildebrand solubility parameter between 19 joules per cubic centimeter (J/Cm³) or less. More specifically, the hydrophobic developer may have a Hildebrand solubility parameter of 10 J/Cm³ or more, 15 J/Cm³ or more, 17 J/Cm³ or more, or 18.5 J/Cm³ or less.

In at least some examples, the hydrophilic developer may have a Hildebrand solubility parameter of 21 J/Cm³ or more. More specifically, the hydrophilic developer may have a Hildebrand solubility parameter of 50 J/Cm³ or less, 35 J/Cm³ or less, 30 J/Cm³ or less, or 22 J/Cm³ or more.

For example, the hydrophobic developer may include an organic developer containing an ether-based solvent, an organic developer containing a ketone-based solvent, an organic developer containing an ester-based solvent, an organic developer containing a hydrocarbon-based solvent, or a combination thereof.

The ether-based solvent, the ketone-based solvent, the ester-based solvent, and the hydrocarbon-based solvent may be defined as in the part of <Solvent>.

In the hydrophobic developer, a lower limit of a content of the ether-based solvent, the ketone-based solvent, the ester-based solvent, or the hydrocarbon-based solvent may be 80 wt % or more, specifically, 90 wt % or more, more specifically, 95 wt % or more, or in particular, 98 wt % or more.

For example, the hydrophilic developer may include distilled water, an alkaline developer, an organic developer containing an alcohol-based solvent, an organic developer containing an amide-based solvent, an organic developer containing a lactate-based solvent, an organic developer containing a sulfoxide-based solvent, or a combination thereof.

The alkaline developer may include, for example, an alkaline aqueous solution in which one or more alkaline compounds such as at least one of sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A range of a content of the alkaline compound in the alkaline developer may be 0.1 percent by weight (wt %) to 20 wt % or less. For example, the alkaline compound may be 0.1 wt % or more, specifically, 0.5 wt % or more, or more specifically, 1 wt % or more. In addition, an upper limit of the content of the alkaline compound in the alkaline developer may be 20 wt % or less, specifically, 10 wt % or less, or more specifically, 5 wt % or less.

Examples of the alcohol-based solvent may include, for example, at least one of a monoalcohol-based solvent such as methanol, ethanol, n-propanol, isopropanol (IPA), 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol; a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol; or a polyhydric alcohol-containing ether-based solvent such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, or dipropylene glycol monopropyl ether.

The amide-based solvent, the lactate-based solvent, and the sulfoxide-based solvent may be defined as in the part of <Solvent>.

In the hydrophilic developer solution, a lower limit of a content of the alcohol-based solvent or the lactate-based solvent may be 80 wt % or more, specifically, 90 wt % or more, more specifically, 95 wt % or more, or in particular, 98 wt % or more.

Specifically, as the developer, toluene, n-BA, PGMEA, PGME, ethanol, IPA, or the like may be used. The developer may further include an organic acid such as an acetic acid, a formic acid, or a citric acid.

More specifically, as the hydrophobic developer, toluene, n-BA, PGMEA, or any combination thereof may be used.

More specifically, as the hydrophilic developer, PGME, ethanol, IPA, or any combination thereof may be used.

In at least one example embodiment, the developer may be a hydrophobic developer, and the unexposed portion 112 may be removed by the developer.

In at least one example embodiment, the developer may be a hydrophilic developer, and the exposed portion 111 may be removed by the developer.

The organic developer may also include a surfactant. Furthermore, during development, the development may be stopped by substituting the organic developer with a solvent that is a different type therefrom.

The resist pattern 115 after the development may be further cleaned. For example, at least one of ultrapure water, a rinse solution, or the like may be used as a cleaning solution. A rinse solution is not particularly limited as long as the rinse solution does not dissolve the resist pattern 115, and a solution including a general organic solvent may be used. For example, the rinse solution may be an alcohol-based solvent or an ester-based solvent. After the cleaning, the rinse solution remaining on the substrate 100 and the resist pattern 115 may be removed. In addition, when ultrapure water is used, water remaining on the substrate 100 and the resist pattern 115 may be removed.

In addition, developers may be used singly or in a combination of two or more.

After the resist pattern 115 is formed as described above, a pattern interconnection substrate may be obtained through etching. The etching may be performed through a known method including dry etching using a plasma gas and wet etching using an alkaline solution, a copper (II) chloride solution, an iron (II) chloride solution, or the like.

After the resist pattern 115 is formed, a pattern deposition may be performed. For example, the pattern deposition may include forming a plating operation. The plating may include, for example, a copper plating, a solder plating, a nickel plating, a gold plating, or the like.

The resist pattern 115 remaining after the etching may be peeled off with an organic solvent. One or more embodiments are not limited thereto, examples of such an organic solvent include PGMEA, PGME, EL, or the like. A peeling method is not particularly limited, but examples thereof may include an immersion method, a spray method, or the like. In addition, the pattern interconnection substrate on which the resist pattern 115 is formed may be a multi-layer interconnection substrate or may have small-diameter through-holes.

In at least one example embodiment, the pattern interconnection substrate may be formed through a method of forming the resist pattern 115, depositing a metal in a vacuum, and then melting the resist pattern 115 with a solution, that is, a lift-off method.

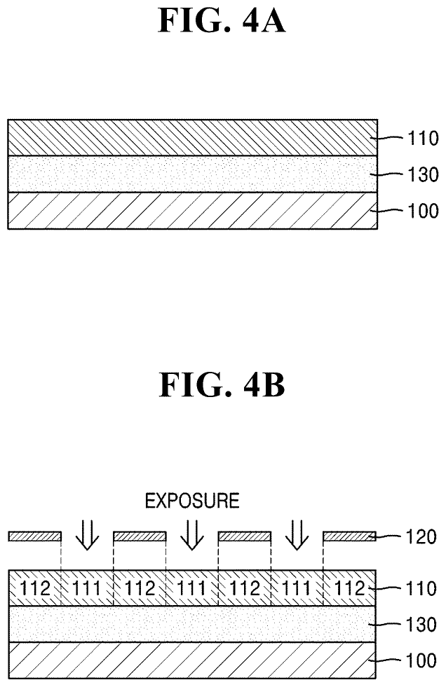

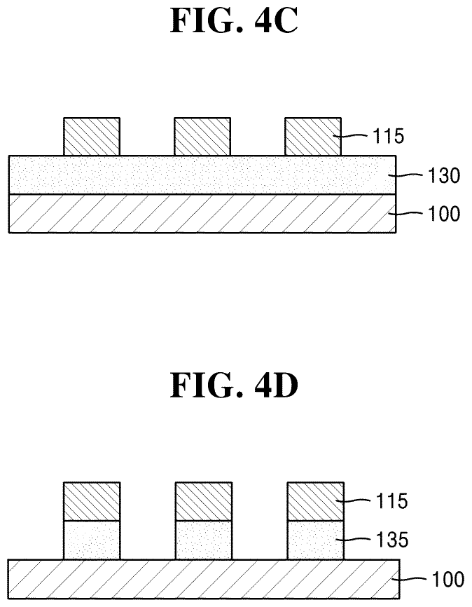

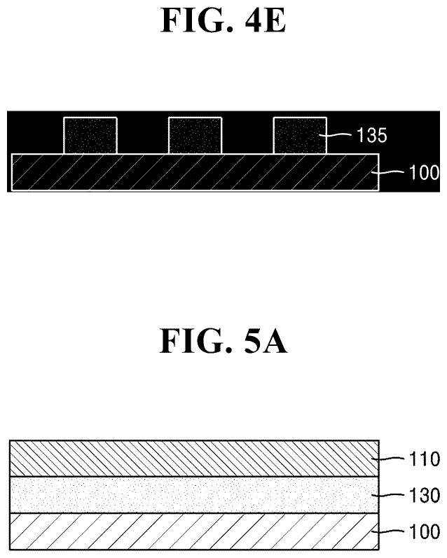

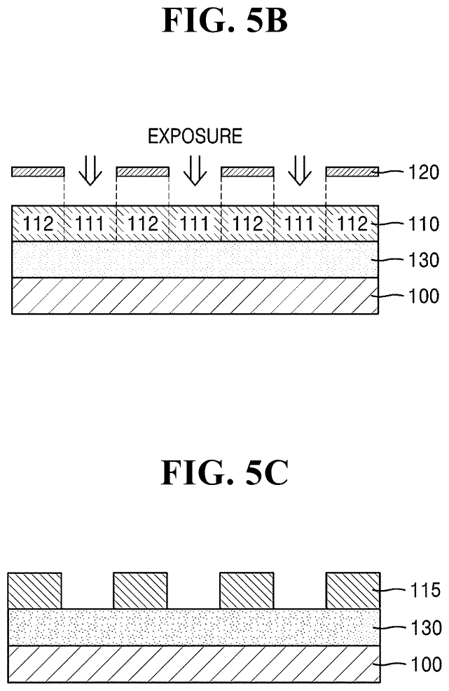

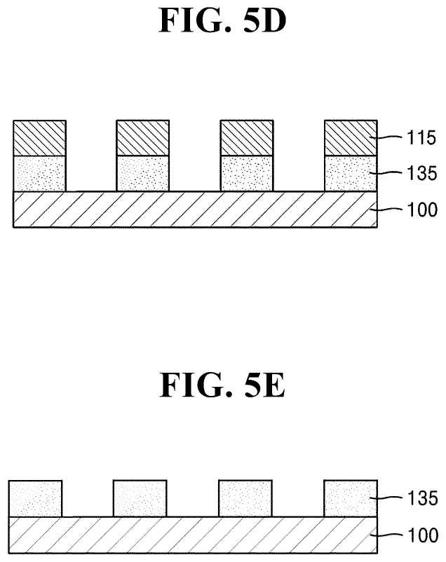

FIGS. 4A to 4E and 5A to 5E are cross-sectional side views illustrating a pattern formation method according to at least one example embodiment. FIGS. 4A to 4E are cross-sectional side views illustrating the pattern formation method using a hydrophobic developer, and FIGS. 5A to 5E are cross-sectional side views illustrating the pattern formation method using a hydrophilic developer.

As shown in FIGS. 4A and 5A, before a resist film 110 is formed on a substrate 100, a material layer 130 may be formed on the substrate 100. The resist film 110 may be formed on the material layer 130. The material layer 130 may include an insulating material (for example, silicon oxide or silicon nitride), a semiconductor material (for example, silicon), or a metal (for example, copper). In some embodiments, the material layer 130 may have a multi-layer structure. A material of the material layer 130 may be different from a material of the substrate 100. For example, the material of the material layer 130 may have etch selectivity compared to the material of the substrate 100.

As shown in FIGS. 4B and 5B, the resist film 110 may be subjected to a pre-exposure bake process and exposed to high-energy rays through a mask 120, and then the resist film 110 may include an exposed portion 111 and an unexposed portion 112.

As shown in FIGS. 4C and 5C, the exposed resist film 110 may be developed by using a developer. As shown in FIG. 4C, when development is performed by using a hydrophobic developer, the unexposed portion 112 may be removed, and as shown in FIG. 5C, when development is performed by using a hydrophilic developer, the exposed portion 111 may be removed.

As shown in FIGS. 4D and 5D, an exposed portion of the material layer 130 may be etched by using a resist pattern 115 as a mask to form a material pattern 135 on the substrate 100.

As shown in FIGS. 4E and 5E, the resist pattern 115 may be removed.

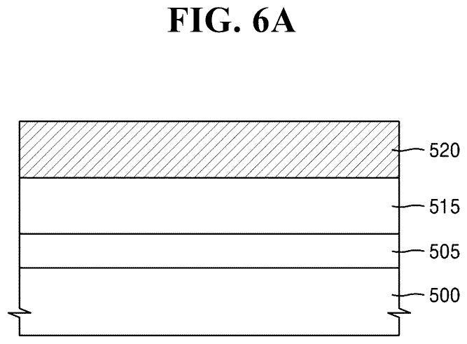

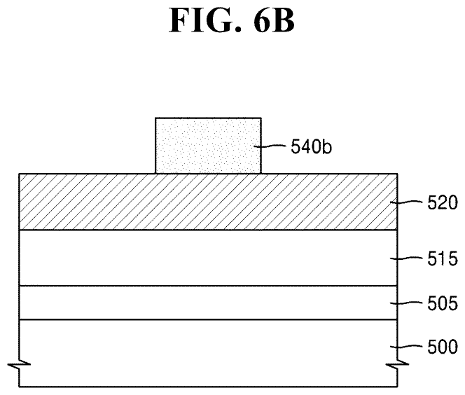

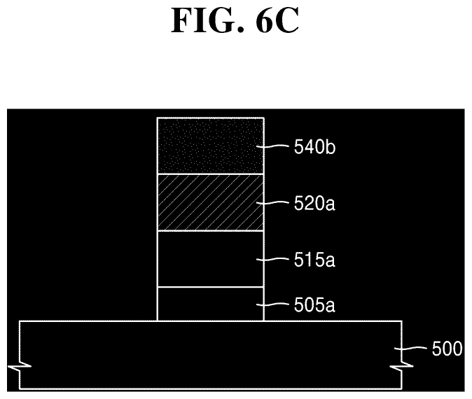

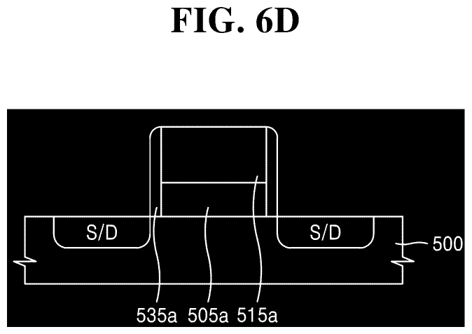

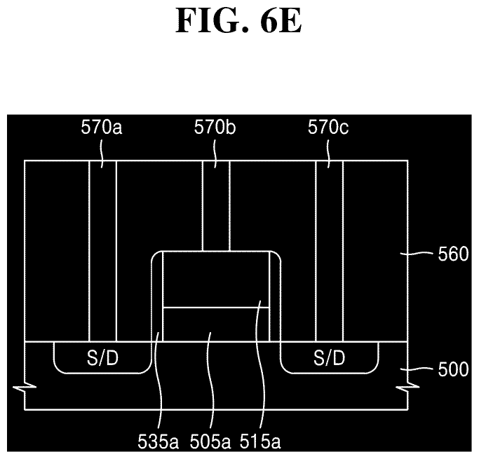

FIGS. 6A to 6E are side cross-sectional views illustrating a method of forming a semiconductor device according to at least one example embodiment.

As shown in FIG. 6A, a gate dielectric 505 (for example, silicon oxide) may be formed on a substrate 500. The substrate 500 may be a semiconductor substrate such as a silicon substrate. A gate layer 515 (for example, doped polysilicon) may be formed on the gate dielectric 505. A hardmask layer 520 may be formed on the gate layer 515.

As shown in FIG. 6B, a resist pattern 540b may be formed on the hardmask layer 520. The resist pattern 540b may be formed by using a resist composition according to at least one example embodiment. The resist composition may include an organic solvent.

As shown in FIG. 6C, the gate layer 515 and the gate dielectric 505 may be etched to form a hardmask pattern 520a, a gate electrode pattern 515a, and a gate dielectric pattern 505a.

As shown in FIG. 6D, a spacer layer may be formed on the gate electrode pattern 515a and the gate dielectric pattern 505a. The spacer layer may be formed by using a deposition process (for example, chemical vapor deposition (CVD)). The spacer layer may be etched to form a spacer 535a (for example, silicon nitride) on sidewalls of the gate electrode pattern 515a and the gate dielectric pattern 505a. After the spacer 535a is formed, ions may be implanted into the substrate 500 to form source/drain impurity regions S/D.

As shown in FIG. 6E, an interlayer insulating film 560 (for example, oxide) may be formed on the substrate 500 to cover the gate electrode pattern 515a, the gate dielectric pattern 505a, and the spacer 535a. Thereafter, electrical contacts 570a, 570b, and 570c connected to the gate electrode pattern 515a and the source/drain impurity regions S/D may be formed in the interlayer insulating film 560. The electrical contacts 570a, 570b, and 570c may be formed of a conductive material (for example, metal). Although not shown, a barrier layer may be formed between a sidewall of the interlayer insulating film 560 and the electrical contacts 570a, 570b, and 570c.

FIGS. 6A to 6E illustrate an example in which a transistor is formed, but the disclosure is not limited thereto.

The resist composition according to at least one example embodiment may be used in a patterning process of forming other types of semiconductor apparatuses.

The disclosure will be described in more detail using the following Examples and Comparative Examples, but the technical scope of the disclosure is not limited only to the following Examples.

### EXAMPLES

### Synthesis Example 1: Synthesis of M1

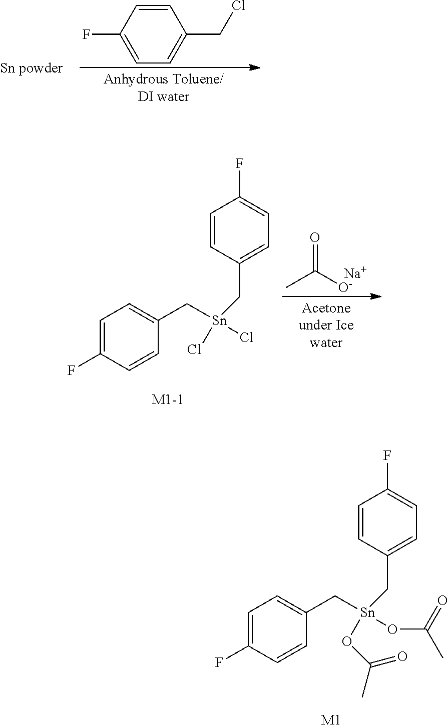

### (1) Synthesis of M1-1

8.2 grams (g) (69.2 millimoles (mmol)) of a Sn powder and 120 ml of dry toluene were put into a 250 milliliters (ml) three-necked flask, and a temperature was raised to 90° C. About 1.0 ml of deionized (DI) water was added, and then 10.0 g (69.2 mmol) of 4-fluorobenzyl chloride was added dropwise for 10 minutes. After heating, refluxing, and stirring were performed at a temperature of 130° C. for 4 hours, an unreacted Sn powder was filtered by using a Buchner funnel. While a solution filtered at the same time was cooled, 6.5 g (yield 36%) of white crystal M1-1, which was a product, was obtained.

### (2) Synthesis of M1

After 1.5 g (3.7 mmol) of M1-1 and 21.0 ml of dry acetone were put into a 50 ml single-necked flask, a temperature was lowered to 0° C. After 0.6 g (7.4 mmol) of sodium acetate was added, stirring was performed for about 12 hours. A solution from which a NaCl salt generated in the solution was filtered by using a 0.45 m filter was concentrated by rotary evaporation and dried under vacuum to obtain M1 (1.6 g) with a yield of 74%.

¹H-NMR (500 MHz, DMSO-d₆): δ ˜6.9 (8H), ˜2.6 (4H), ˜1.6 (6H)

### Preparation Example: Preparation of Casting Solution

The organometallic compound and the additive synthesized in Synthetic Example 1 were dissolved in an amount of 2 wt % in cyclopentanone to prepare casting solutions A-1 and A-2. Here, a weight ratio of the organometallic compound to the additive is 1:1.5.

In addition, casting solution B-1 was prepared having the same composition as casting solution A-1, except that casting solution B-1 did not include any additive.

TABLE 1

| Casting | | | Organometallic | |
|---|---|---|---|---|
| solution | Organometallic | Addi- | compound:additive | Casting |
| No. | compound | tive | (weight ratio) | solvent |
| A-1 | M1 | A1 | 2.5:1 | Cyclopentanone |
| A-2 | M1 | A1 | 2.5:1 | EL |
| B-1 | M1 | — | — | EL |

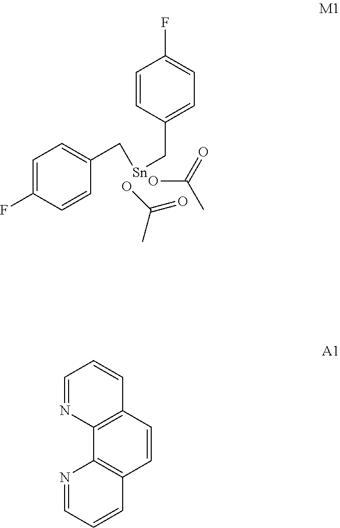

### Evaluation Example 1: Thin Film Phenomenon Evaluation 1

### (1) Terminology

In Examples 1-1 to 1-4 and Comparative Examples 1-1 and 2-1, E₀ denotes an exposure amount at a time point at which a thin film starts to be cured, and Ei denotes an exposure amount at a saturation point at which the thin film is completely cured (e.g., no longer becomes thicker).

In Examples 2-1 to 2-4, E₀ denotes an exposure amount at a point at which a thin film starts to be developed, and Ei denotes an exposure amount at a point at which the thin film is completely developed (e.g., the thin film no longer becomes thinner).

γ is a value calculated from a contrast curve through Equation 1 below.

$$γ = {[ log ( \frac{{E}_{1}}{{E}_{0}} ) ]}^{- 1} \qquad Equation 1$$

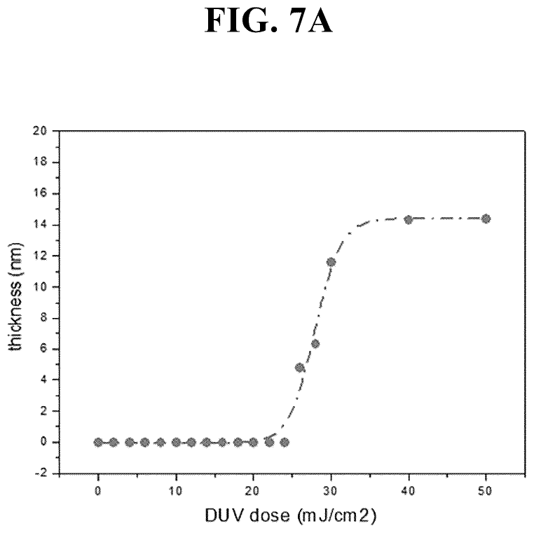

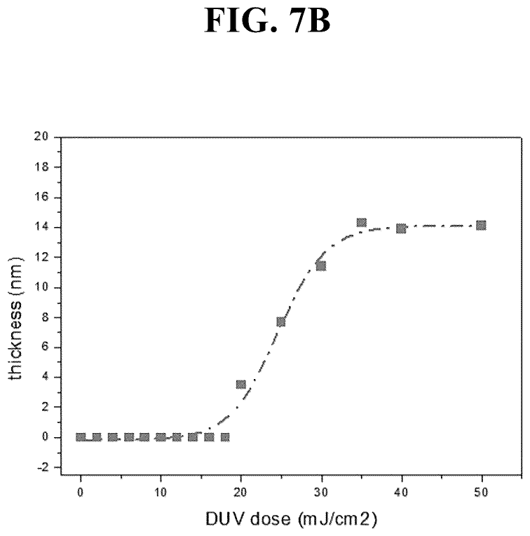

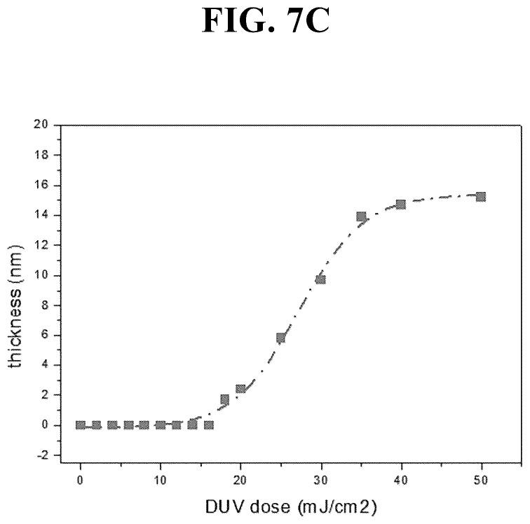

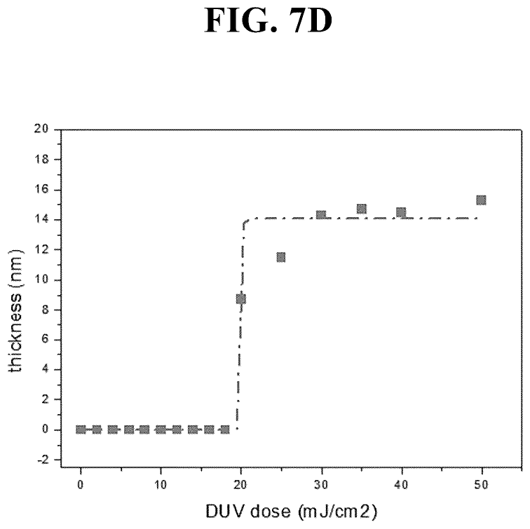

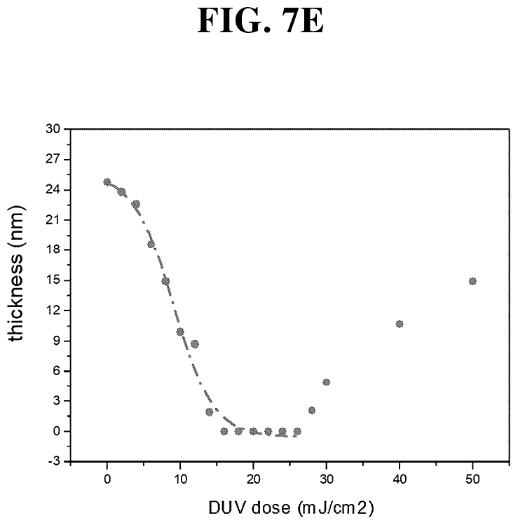

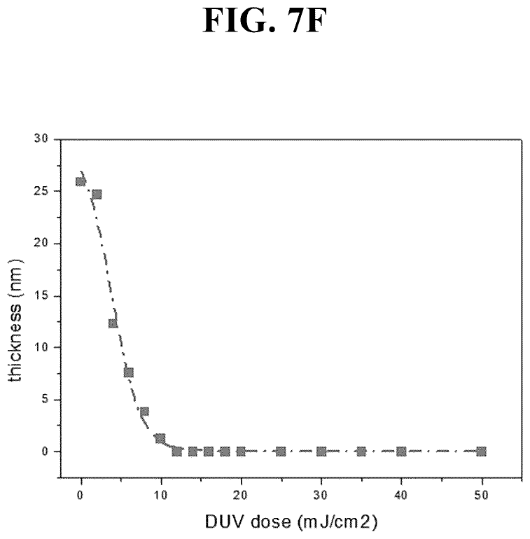

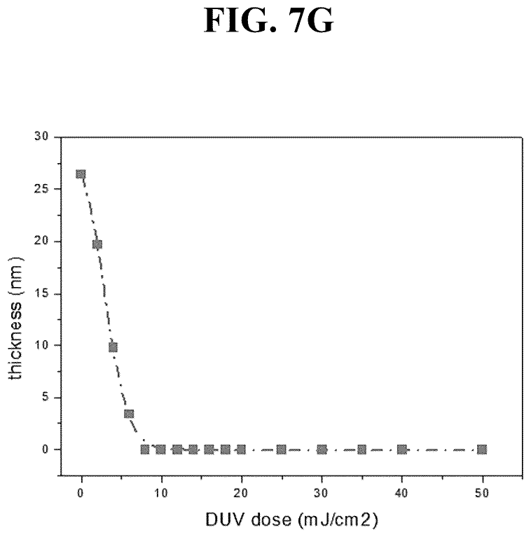

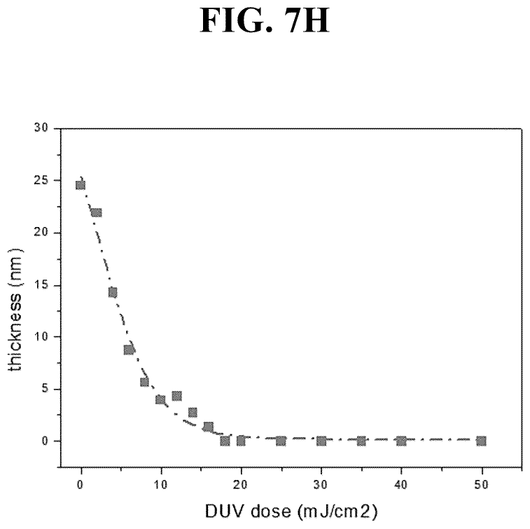

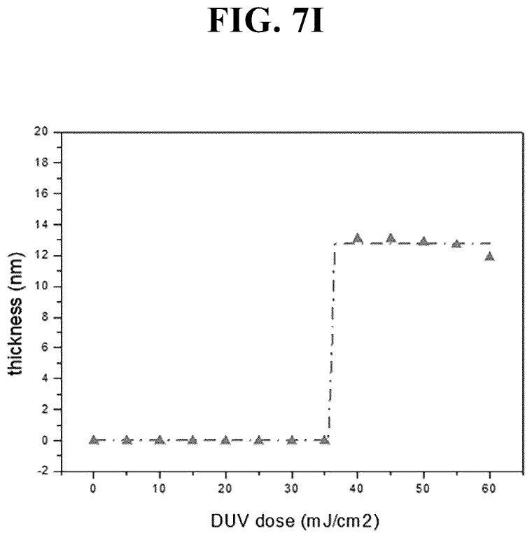

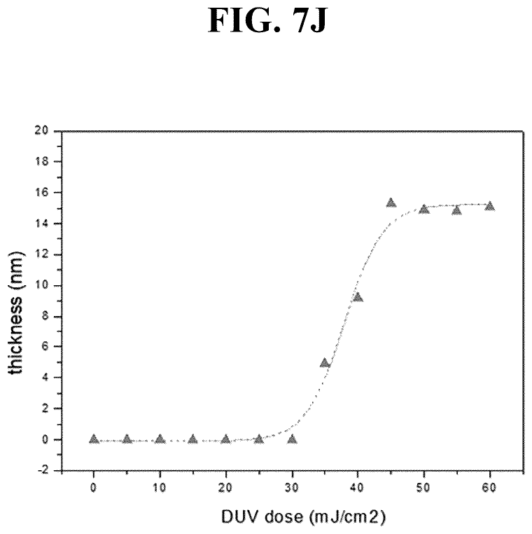

A silicon wafer with a diameter of 8 inches was cut in quarters, treated with O₂ plasma for 30 minutes, and then spin-coated with each of casting solutions A-1, A-2, and B-1 at a speed of 1,200 revolutions per minute (rpm) for 1 minute. Thereafter, PAB was performed at a temperature of 90° C. for 1 minute to form a film with an initial thickness. Next, a mask (4 centimeters (cm)×4 cm) with rectangular holes (1 cm×1 cm) and a thickness of 1 cm was placed on the film, each hole was exposed to DUV with a wavelength of 254 nm in a dose of 0 mJ/cm² to 50 mJ/cm², and PEB was performed at a temperature of 180° C. for 1 minute. The dried film was soaked in a developer shown in Table 2 below at a temperature of 25° C. for 60 seconds, developed, and then washed with DI water. Thereafter, a thickness of the remaining film was measured and shown in FIGS. 7A to 7J.

TABLE 2

| | Casting | | | | | | |
|---|---|---|---|---|---|---|---|
| | solution | Developer | Tone | E₀ | E₁ | γ | Graph |
| Example 1-1 | A-2 | PGMEA:AA | NTD | 23 | 32 | 7.0 | FIG. 7A |
| | | (98:2 wt %) | | | | | |
| Example 1-2 | A-1 | PGMEA:AA | NTD | 17 | 32 | 3.6 | FIG. 7B |
| | | (98:2 wt %) | | | | | |
| Example 1-3 | A-1 | n-BA | NTD | 17 | 37 | 3.0 | FIG. 7C |
| Example 1-4 | A-1 | Toluene | NTD | 18 | 22 | 11.5 | FIG. 7D |
| Example 2-1 | A-2 | Isopropyl | PTD | 5 | 13 | 2.4 | FIG. 7E |
| | | alcohol | | | | | |
| Example 2-2 | A-1 | Isopropyl | PTD | 4 | 9 | 2.8 | FIG. 7F |
| | | alcohol | | | | | |
| Example 2-3 | A-1 | Ethanol | PTD | 2 | 7 | 1.8 | FIG. 7G |
| Example 2-4 | A-1 | PGME | PTD | 2 | 8 | 1.7 | FIG. 7H |
| Comparative | B-1 | PGMEA:AA | NTD | 34 | 38 | 20.7 | FIG. 7I |
| Example 1-1 | | (98:2 wt %) | | | | | |
| Comparative | B-1 | Isopropyl | NTD | 28 | 45 | 4.9 | FIG. 7J |
| Example 2-1 | | alcohol | | | | | |

Referring to FIGS. 7A to 7J, it was confirmed that casting solutions A-1 and A-2 including additives exhibited characteristics of both positive and negative-type resist compositions according to the hydrophilicity of a developer, but in casting solution B-1 not including additives, an exposed region was not removed even when the polarity of a developer was changed. Specifically, casting solutions A-1 and A-2 exhibited the characteristics of a negative-type resist composition when a hydrophobic developer was used, whereas casting solutions A-1 and A-2 exhibited the characteristics of a positive-type resist composition when a hydrophilic developer was used.

### Evaluation Example 2: Thin Film Phenomenon Evaluation 2

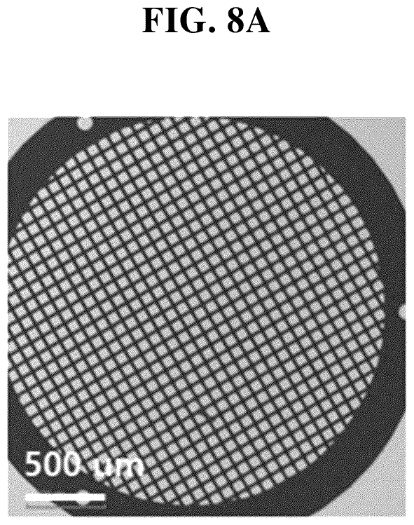

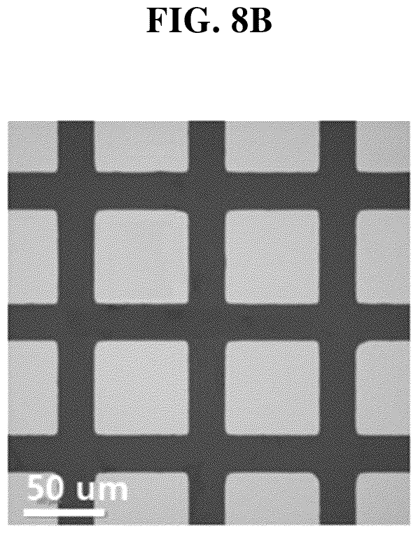

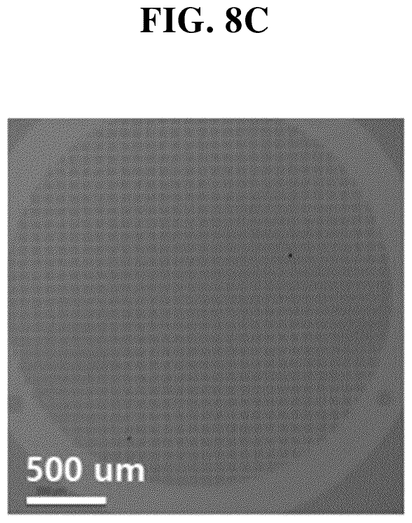

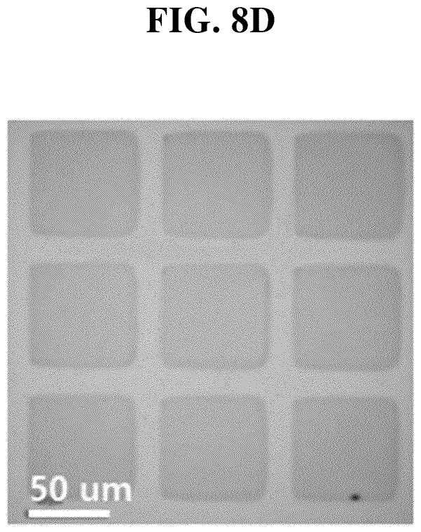

A silicon wafer with a diameter of 8 inches was cut in quarters, treated with O₂ plasma for 30 minutes, and then spin-coated with casting solution A-1 at a speed of 1,200 rpm for 1 minute. Thereafter, PAB was performed at a temperature of 90° C. for 1 minute to form a film with an initial thickness of about 50 nm. Next, a transmission electron microscopy (TEM) copper grid (with a mesh size of 300, a grid line width of about 30 am, and a pore size of about 50 am) was placed on the film and used as a mask to expose the film to DUV with a wavelength of 254 nm in a dose of 120 mJ/cm², and PEB was performed at a temperature of 180° C. for 1 minute. The dried film was soaked in n-BA or IPA as a developer at a temperature of 25° C. for 60 seconds, developed, and then washed with DI water. Next, surface images were captured by using an optical microscope and shown in FIGS. 8A to 8D. FIGS. 8A and 8B show a case in which development is performed by using IPA, and FIGS. 8C and 8D show a case in which development is performed by using n-BA. FIG. 8B is an enlarged view of a part of FIG. 8A, and FIG. 8D is an enlarged view of a part of FIG. 8C.

### Evaluation Example 3: Water Contact Angle (WCA) Evaluation

A silicon wafer with a diameter of 8 inches was cut in quarters, treated with O₂ plasma, and then spin-coated with casting solution A-1 at a speed of 1,200 rpm for 1 minute. Thereafter, PAB was performed at a temperature of 90° C. for 1 minute to form a film with a certain initial thickness. Next, a mask (4 cm×4 cm) with rectangular holes (1 cmxl cm) and a thickness of 1 cm was placed on the film, each hole was exposed to DUV with a wavelength of 254 nm in a dose of 0 mJ/cm² to 50 mJ/cm², and PEB was performed at a temperature of 180° C. for 1 minute. The dried film was soaked in isopropyl alcohol as a developer at a temperature of 25° C. for 60 seconds, developed, and then washed with DI water. Next, 3 μL of water was dropped into each hole, and a water contact angle (unit: °) was measured. Results thereof are shown in Table 3 below.

TABLE 3

| Casting | Dose (mJ/cm²) | | | | | | | |
|---|---|---|---|---|---|---|---|---|
| solution | 0 | 2 | 5 | 10 | 20 | 30 | 40 | 50 |
| A-1 | 73.5 | 71.3 | 68.2 | 54.3 | 55.1 | 54.3 | 51.7 | 54.9 |

Referring to Table 3 above, it was seen that a water contact value of resist composition A-1 was significantly changed before and after DUV irradiation, and thus it was confirmed that the surface properties of a thin film is changed from hydrophobicity to hydrophilicity.

Embodiments may provide a pattern formation method using a resist composition of which properties change according to a developer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A pattern formation method comprising:
forming a resist film using a resist composition comprising an organometallic compound and an additive, the organometallic represented by Formula 1 and the additive represented by Formula 2;
forming an exposed portion of the resist film and an unexposed portion of the resist film by exposing at least a portion of the resist film to high-energy rays; and
developing the exposed resist film using a developer, wherein i) the developer is a hydrophobic developer, and the unexposed portion is removed in the developing; or ii) the developer is a hydrophilic developer, and the exposed portion is removed in the developing, 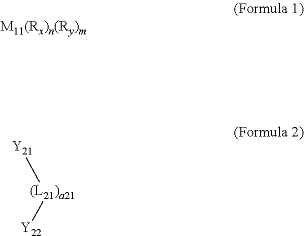
wherein, in Formulas 1 and 2,
M₁₁ is at least one of indium (In), tin (Sn), antimony (Sb), tellurium (Te), thallium (Tl), lead (Pb), bismuth (Bi), or polonium (Po),
Rₓ is *—X₁—Y₁,
R_{y} is *-(L₁)ₐ₁-(R₁)_{b1},
n is an integer from 0 to 6,
m is an integer from 1 to 6,
m+n is 6 or less,
a plurality of Rₓ are identical to or different from each other,
a plurality of R_{y} are identical to or different from each other,
X₁ is at least one of O, OC(═O), C(═O)O, OS(═O), S(═O)O, OS(═O)₂, S(═O)₂O, S, SC(═O), or C(═O)S,
Y₁ is at least one of hydrogen, deuterium, or a linear, branched, or cyclic C₁-C₃₀ monovalent hydrocarbon group optionally containing a heteroatom,
L₁ is a linear, branched, or cyclic C₁-C₃₀ divalent hydrocarbon group optionally containing a heteroatom,
a1 is an integer from 0 to 4,
R₁ is a linear, branched, or cyclic C₁-C₃₀ monovalent hydrocarbon group optionally containing a heteroatom, wherein two adjacent groups in a plurality of R₁ are optionally bonded to each other to form a condensed ring,
b1 is an integer from 1 to 4,
Y₂₁ and Y₂₂ are each independently a linear, branched, or cyclic C₁-C₃₀ divalent hydrocarbon group including one or more selected from an oxygen atom, a sulfur atom, a nitrogen atom, and a phosphorus atom as a heteroatom,
L₂₁ is a single bond, a double bond, or a linear, branched, or cyclic C₁-C₃₀ divalent hydrocarbon group,
a21 is an integer from 1 to 4, and
adjacent two of Y₂₁, Y₂₂, and L₂₁ are optionally bonded to each other to form a condensed ring.

2. The pattern formation method of claim 1, wherein
the hydrophobic developer has a Hildebrand solubility parameter of 19 joules per cubic centimeter (J/Cm³) or less, and
the hydrophilic developer has a Hildebrand solubility parameter of 21 J/Cm³ or more.

3. The pattern formation method of claim 1, wherein the hydrophobic developer comprises an organic developer including at least one of an ether-based solvent, a ketone-based solvent, an ester-based solvent, or a hydrocarbon-based solvent, and
the hydrophilic developer comprises at least one of distilled water, an alkaline developer, an alcohol-based solvent, an amide-based solvent, a lactate-based solvent, a sulfoxide-based solvent, or a combination thereof.

4. The pattern formation method of claim 1, wherein the hydrophobic developer comprises at least one of toluene, n-butyl acetate, propylene glycol monomethyl ether acetate, or a combination thereof, and
the hydrophilic developer comprises at least one of propylene glycol monomethyl ether, ethanol, isopropanol, or a combination thereof.

5. The pattern formation method of claim 1, wherein Mn is at least one of tin (Sn), antimony (Sb), tellurium (Te), or bismuth (Bi).

6. The pattern formation method of claim 1, wherein in Formula 1
n is an integer from 1 to 4,
m is an integer from 1 to 4, and
M₁₁ is Sn.

7. The pattern formation method of claim 1, wherein X₁ at least one of is O, OC(═O), C(═O)O, S, SC(═O), or C(═O)S, and
Y₁ is at least one of hydrogen, deuterium, a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group.

8. The pattern formation method of claim 1, wherein
L₁ is a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group, or a combination thereof,
a1 is 0, 1, or 2, and
R₁ is at least one of a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group, or a combination thereof.

9. The pattern formation method of claim 1, wherein the organometallic compound represented by Formula 1 is represented by at least one of Formulas 1-1 to 1-4 below:

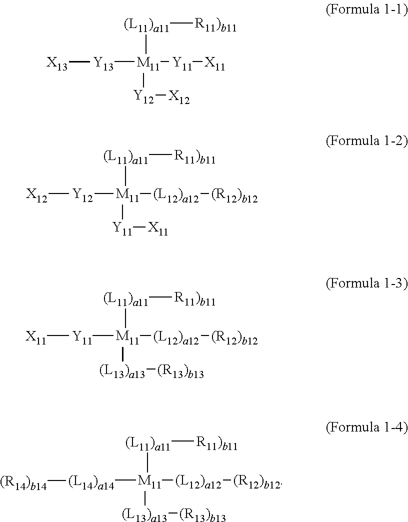

10. The pattern formation method of claim 1, wherein the organometallic compound represented by Formula 1 is at least one of Group I below: 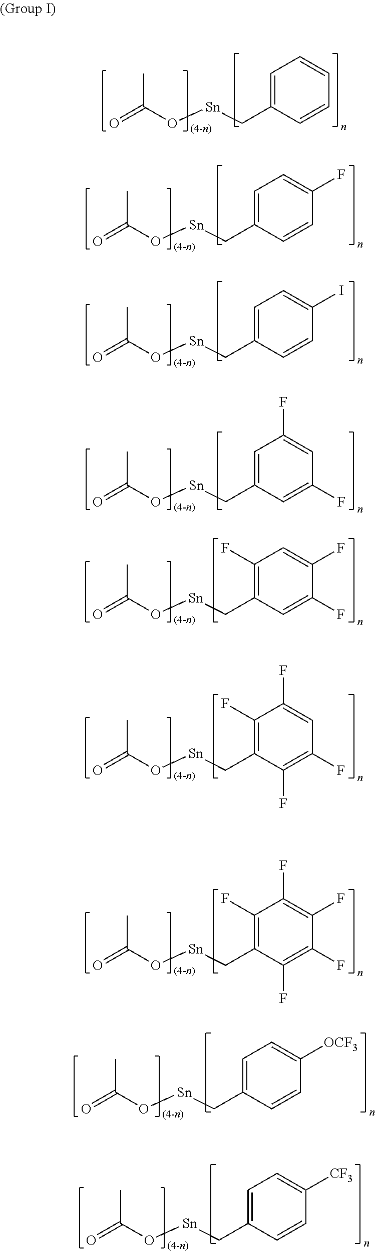 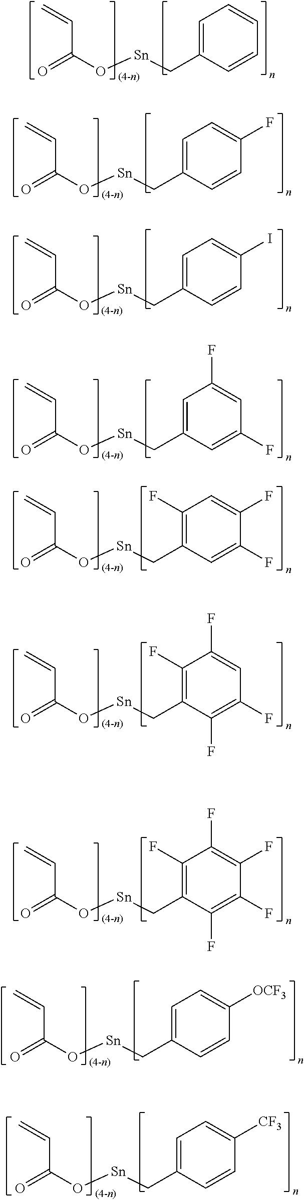 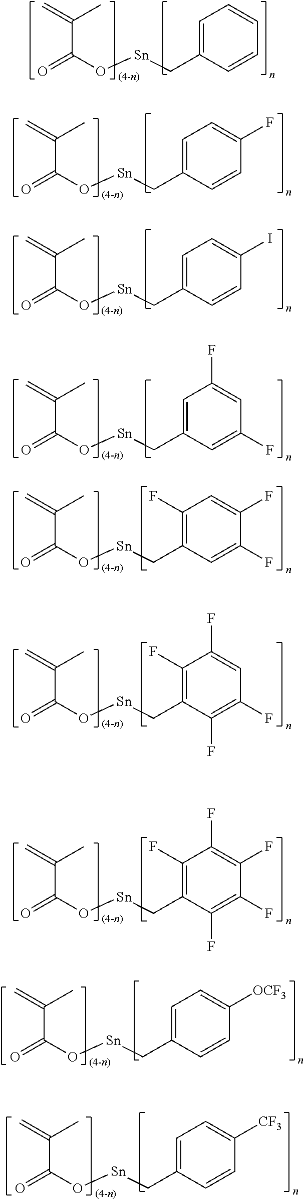 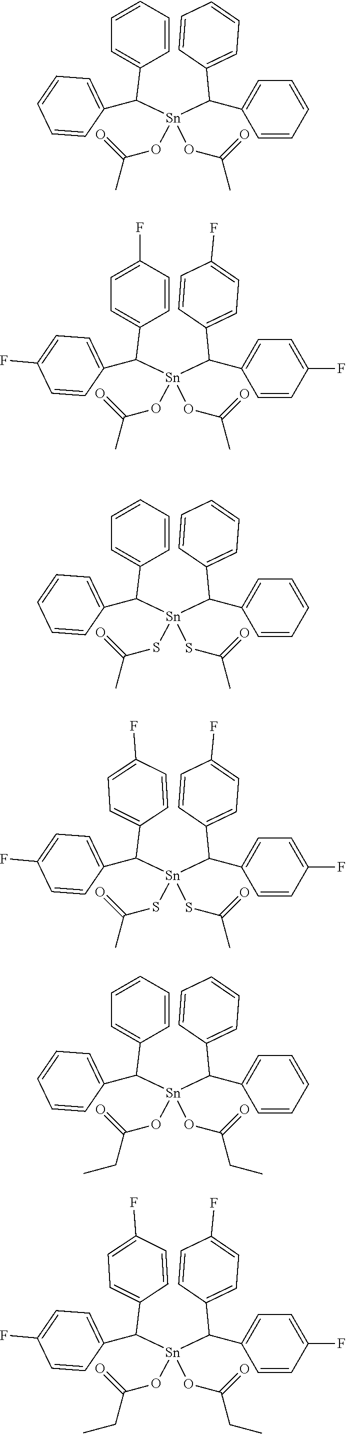 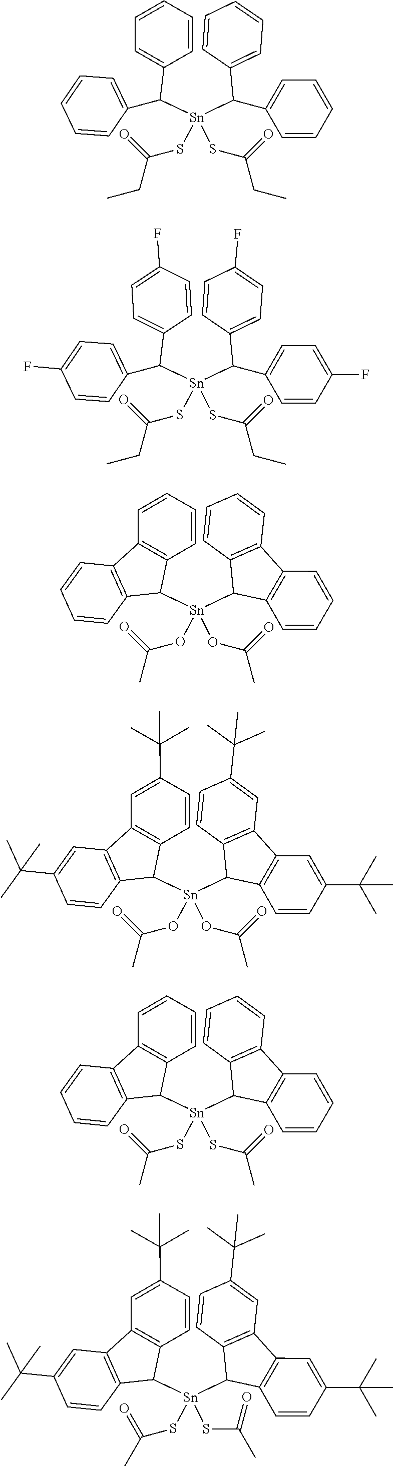 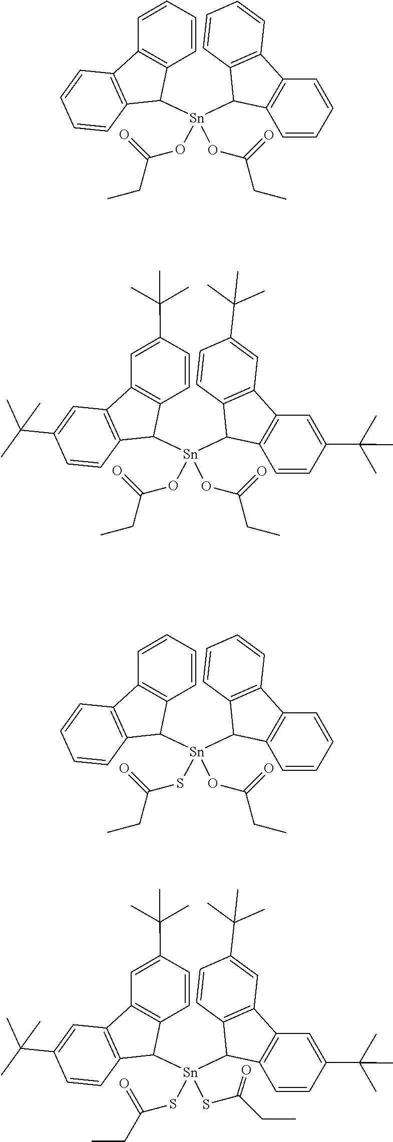 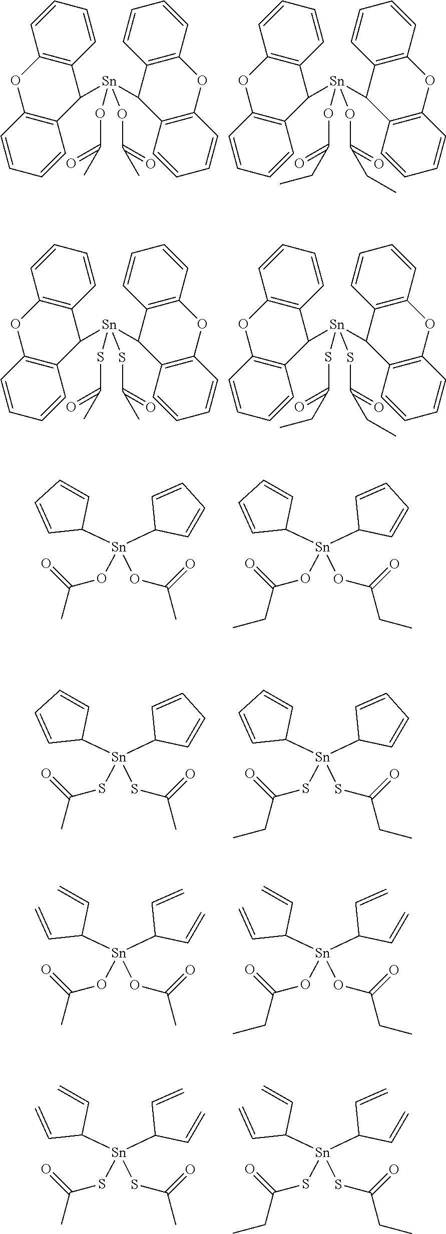 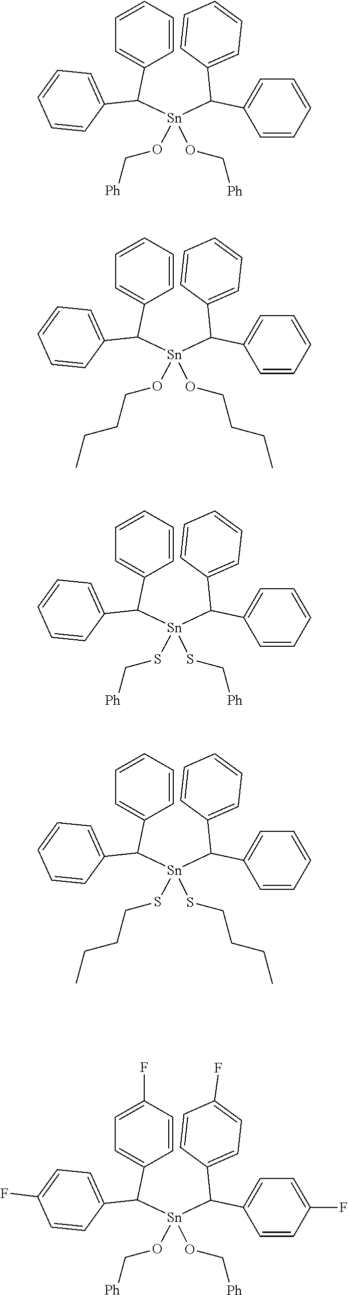 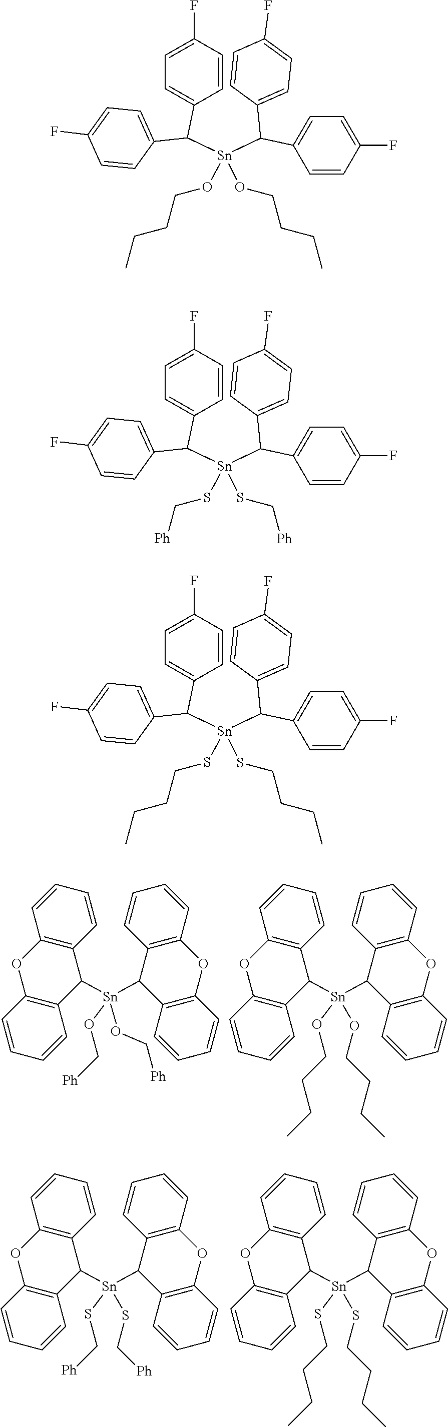 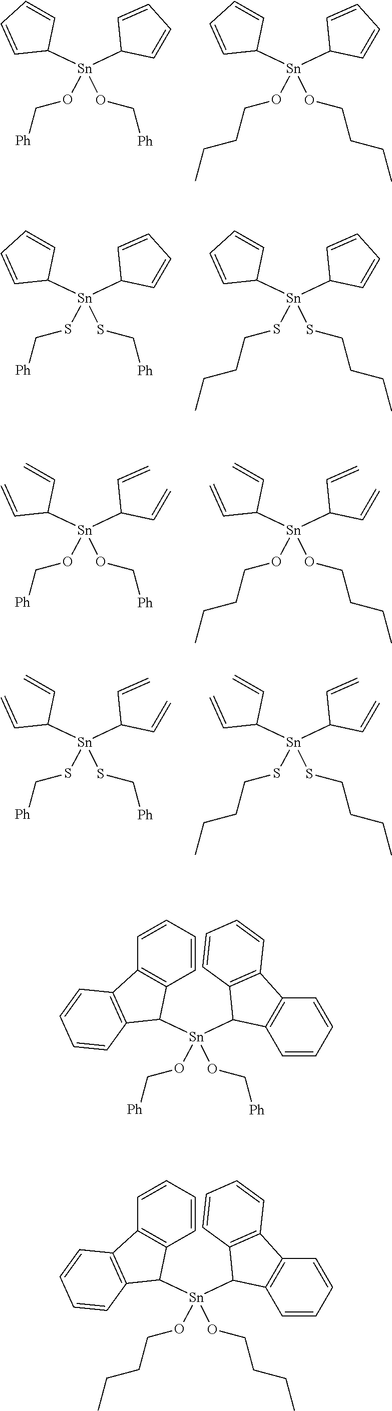 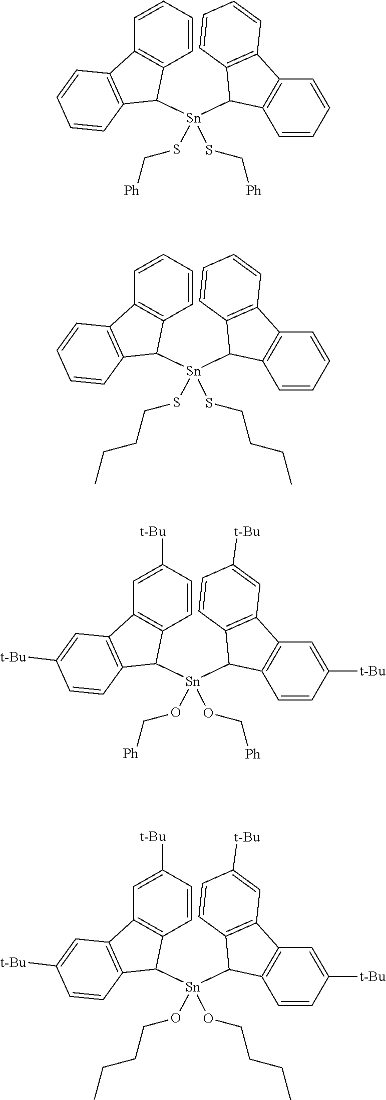 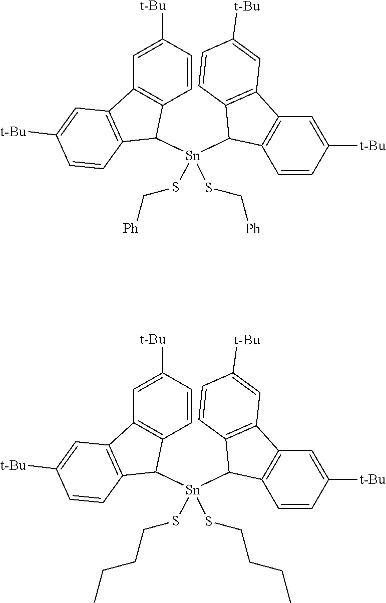
wherein, in Group I, n is an integer from 1 to 4.

11. The pattern formation method of claim 1, wherein Y₂₁ is represented by at least one of Formulas 4-1 to 4-5 below, and
Y₂₂ is represented by at least one of Formulas 4-6 to 4-10 below: 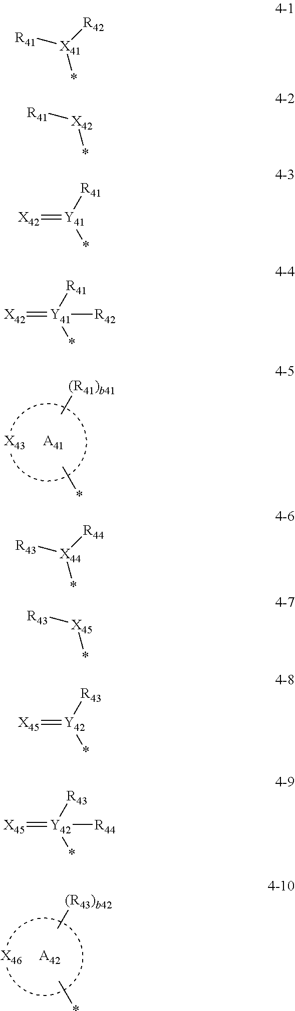
wherein, in Formulas 4-1 to 4-10,
X₄₁ and X₄₄ are each independently N or P,
X₄₂ and X₄₅ are each independently O or S,
X₄₃ and X₄₆ are each independently O, S, N, or P,
Y₄₁ and Y₄₂ are each independently C, S, or P,
A₄₁ is a C₁-C₃₀ heterocyclic group comprising X₄₃ as a ring member,
A₄₂ is a C₁-C₃₀ heterocyclic group comprising X₄₆ as a ring member,
R₄₁ to R₄₄ are each independently hydrogen, deuterium, a halogen, a cyano group, a nitro group, a hydroxyl group, a thiol group, an amino group, a carboxylate group, or a linear, branched, or cyclic C₁-C₃₀ divalent hydrocarbon group,
b41 and b42 are each independently an integer from 1 to 10, and
* is a binding site with an adjacent atom.

12. The pattern formation method of claim 11, wherein A₄₁ and A₄₂ are each independently i) a monovalent group derived from a first ring, ii) a monovalent group derived from a condensed ring in which two or more first rings are condensed with each other, or iii) a monovalent group derived from a condensed ring in which one or more first rings and one or more second rings are condensed with each other,
wherein the first ring is tetrahydropyrane, dihydropyrane, pyrane, tetrahydrothiopyrane, dihydrothiopyrane, thiopyrane, tetrahydrofurane, dihydrofurane, tetrahydrothiophene, dihydrothiophene, piperidine, tetrahydropyridine, dihydropyridine, pyrrolidine, dihydropyrrole, pyrrole, imidazole, pyrazole, furan, thiophene, oxazole, thiazole, pyridine, pyrazine, pyridazine, pyrimidine, or triazine, and
the one or more second rings are each cyclopentane, cyclopentadiene, cyclohexane, cyclohexene, cyclohexadiene, benzene, or naphthalene.

13. The pattern formation method of claim 1, wherein the additive represented by Formula 2 is represented by Formula 2-1 below: 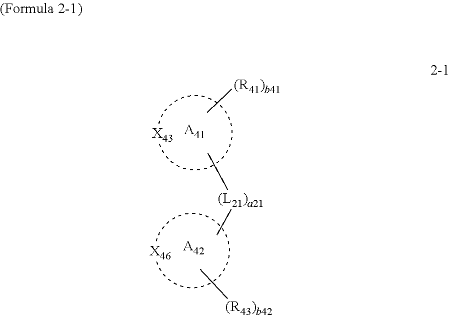
wherein, in Formula 2-1,
X₄₃ and X₄₆ are each independently O, S, N, or P,
A₄₁ is a C₁-C₃₀ heterocyclic group comprising X₄₃ as a ring member,
A₄₂ is a C₁-C₃₀ heterocyclic group comprising X₄₆ as a ring member,
L₂₁ is a single bond, a double bond, or a linear, branched, or cyclic C₁-C₃₀ divalent hydrocarbon group,
a21 is an integer from 1 to 4,
R₄₁ and R₄₃ are each independently a linear, branched, or cyclic C₁-C₃₀ divalent hydrocarbon group,
b41 and b42 are each independently an integer from 1 to 10, and
adjacent two of R₄₁, R₄₃, and L₂₁ are optionally bonded to each other to form a condensed ring.

14. The pattern formation method of claim 1, wherein the additive represented by Formula 2 is represented by at least one of Formulas 2-21 to 2-26 below: 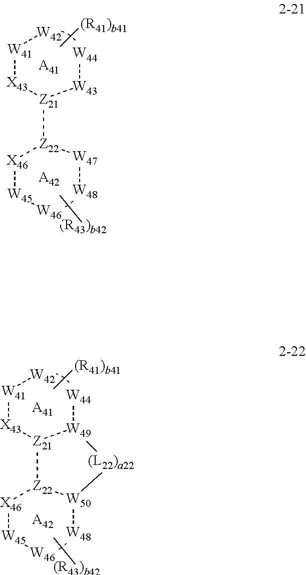 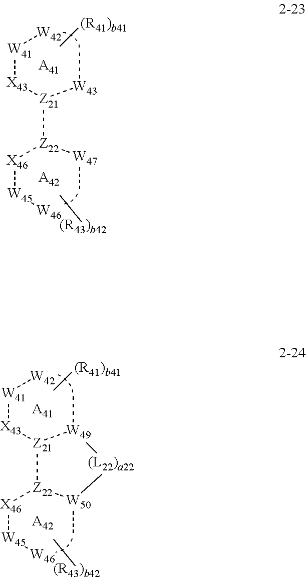 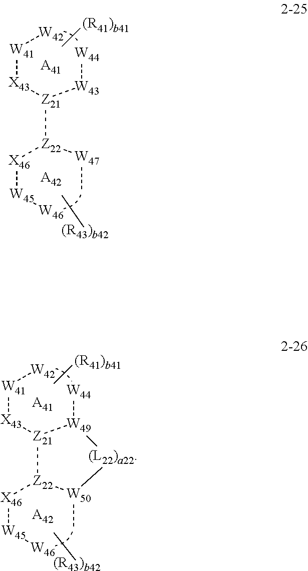
wherein, in Formulas 2-21 to 2-26,
X₄₃ and X₄₆ are each independently O, S, N, or P,
A₄₁ is a C₁-C₃₀ heterocyclic group comprising Z₂₁, X₄₃, W₄₁ to W₄₄, and W₄₉ as ring members,
A₄₂ is a C₁-C₃₀ heterocyclic group comprising Z₂₂, X₄₆, W₄₅ to W₄₈, and W₅₀ as ring members,
Z₂₁ and Z₂₂ are each independently C or N,
W₄₁ to W₅₀ are each independently C(R₄₁ₐ), C(R₄₁ₐ)(R_{41b}), C(R₄₃ₐ), C(R₄₃ₐ)(R_{43b}), or N, a bond between Z₂₁ and Z₂₂, a bond between Z₂₁ and X₄₃, a bond between X₄₃ and W₄₁, a bond between W₄₁ and W₄₂, a bond between Z₂₁ and W₄₃, a bond between W₄₃ and W₄₄, a bond between Z₂₂ and X₄₆, a bond between X₄₆ and W₄₅, a bond between W₄₅ and W₄₆, a bond between Z₂₂ and W₄₇, a bond between W₄₇ and W₄₈, a bond between W₄₄ and W₄₉, a bond between W₄₉ and Z₂₁, a bond between Z₂₂ and W₅₀, a bond between W₄₈ and W₅₀, a bond between W₄₂ and W₄₃, a bond between W₄₆ and W₄₇, a bond between W₄₂ and W₄₉, and a bond between W₄₆ and W₅₀ are each a single bond or a double bond,
L₂₂ is a single bond; a double bond; or a C₁-C₃₀ alkylene group and/or a C₂-C₃₀ alkenylene group, each unsubstituted or substituted with deuterium, a halogen, a hydroxyl group, a cyano group, a C₁-C₂₀ alkyl group, a C₁-C₂₀ halogenated alkyl group, or a combination thereof,
a22 is an integer from 1 to 4,
R₄₁, R₄₃, R₄₁ₐ, R_{41b}, R₄₃ₐ, and R_{43b} are each independently a linear, branched, or cyclic C₁-C₃₀ divalent hydrocarbon group, and
b41 and b42 are each independently an integer from 1 to 10.

15. The pattern formation method of claim 1, wherein the additive represented by Formula 2 is selected from Group II below:

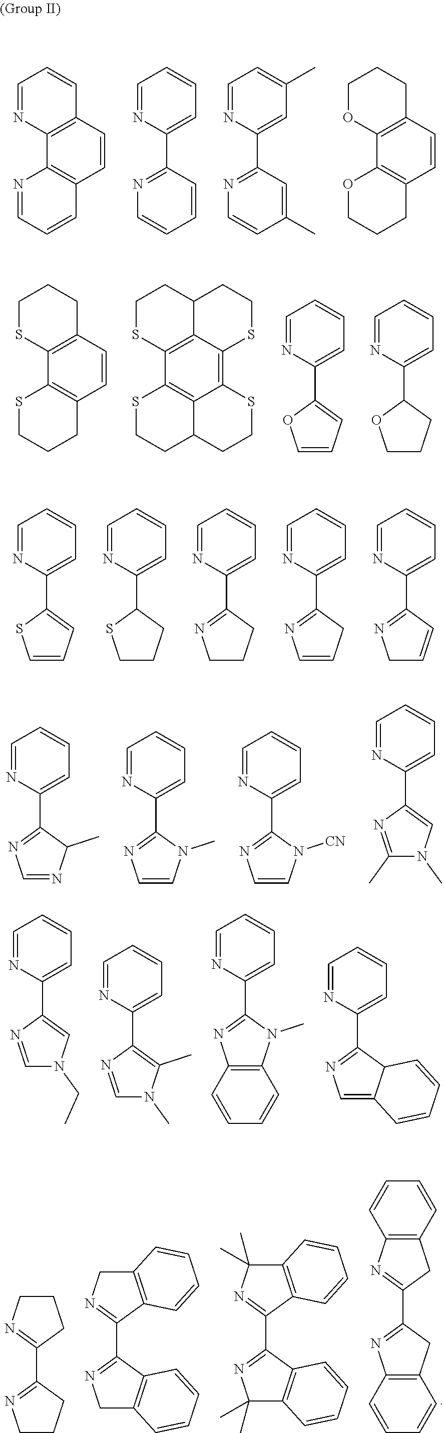

16. The pattern formation method of claim 1, wherein
the organometallic compound is included in an amount of about 0.01 parts by weight to about 99.99 parts by weight, with respect to 100 parts by weight of the resist composition, and
the additive is included in an amount of about 0.01 parts by weight to about 99.99 parts by weight, with respect to the 100 parts by weight of the resist composition.

17. The pattern formation method of claim 1, wherein the additive is included in an amount of about 0.1 parts by weight to about 100,000 parts by weight, with respect to 100 parts by weight of the organometallic compound.

18. The pattern formation method of claim 1, wherein the resist composition further comprises a polar aprotic solvent.

19. The pattern formation method of claim 1, wherein a difference between a water contact angle of the unexposed portion and a water contact angle of the exposed portion is 100 or more.

20. The pattern formation method of claim 1, wherein the exposing includes irradiating at least one of ultraviolet rays, deep ultraviolet (DUV) rays, extreme ultraviolet (EUV) rays, X-rays, γ-rays, electron beams (EBs), or a-rays onto the expose portion of the resist film.
